(19) United States
(12) Patent Application Publication
(10) Pub. No.: US 2005/0218480 A1
(43) Pub. Date: Oct. 6, 2005

(54) Device mounting board and semiconductor apparatus using device mounting board

(76) Inventors: Ryosuke Usui, Ichinomiya-City (JP); Takeshi Nakamura, Sawa-Gun (JP); Hideki Mizuhara, Bisai-City (JP)

Correspondence Address: FISH & RICHARDSON P.C., CITIGROUP CENTER 52ND FLOOR, 153 EAST 53RD STREET, NEW YORK, NY, 10022-4611, US

(21) Appl. No.: 11/088,137

(22) Filed: Mar. 23, 2005

(30) Foreign Application Priority Data
Mar. 31, 2004 (JP) 2004-105042
Mar. 31, 2004 (JP) 2004-103818

(51) Int. Cl. H01L 23/58

(52) U.S. Cl. 257/632

(57) ABSTRACT

The device mounting board according to the first embodiment has the structure in which an dielectric resin film and a photoimageable solder resist film are sequentially laminated on an upper surface of a base material. The device mounting board also has the structure in which the dielectric resin film and the photoimageable solder resist film are sequentially laminated on a lower surface of the base material. The photoimageable solder resist film contains the cardo type polymer.

### BACKGROUND OF THE INVENTION

1. Field of the Invention

The present invention relates to a device mounting board, a manufacturing method thereof, and a semiconductor apparatus using the device mounting board.

2. Description of the Related Art

Recently, multifunction and high performance of portable electronic devices such as a cellular phone, PDA, DVC, and DSC are accelerated, so that miniaturization and weight reduction are necessary in order that such electronic devices are accepted in the market. A highly integrated system-LSI is required in order to realize the miniaturization and the weight reduction. On the other hand, the ease-to-use and convenient electronic devices are demanded, and the multifunction and the high performance are demanded for LSIs used for the electronic devices. Therefore, while the number of I/Os are increased as an LSI chip is integrated, and the miniaturization of a package itself is also demanded. In order to achieve compatibility between the integration of the LSI chip and the miniaturization of the package, development on the semiconductor package suitable to the high-density board mounting of the semiconductor component is strongly demanded. In order to response such demands, various package technologies called as CSP (Chip Size Package) are being developed.

BGA (Ball Grid Array) is well known as an example of such packages. In BGA, the semiconductor chip is mounted on a package board, and solder balls are formed as external terminals in an area array on the opposite surface after the semiconductor chip on the package board is molded with resin. In BGA, because the mounting area is achieved over the surface, the package can be relatively easily miniaturized. Further, the high-accuracy mounting technology is not required because it is unnecessary to be compatible with a narrow pitch on the side of a circuit board. Therefore, even if the package is somewhat expensive, the use of BGA enables the mounting cost to be reduced as a whole.

FIG. 15 is a view showing a schematic configuration of the conventional BGA. BGA 100 has a structure in which an LSI chip 102 is mounted on a glass epoxy board 106 through an adhesive layer 108. The LSI chip 102 is molded by a sealing resin 110. The LSI chip 102 and the glass epoxy board 106 are electrically connected to each other by metal wires 104. Solder balls 112 are arranged in an array on the backside of the glass epoxy board 106. BGA 100 is mounted on a printed wiring board through the solder balls 112.

An example of other CSPs is described in Japanese Patent Laid-Open Publication No. 2002-94247. A system in package on which a high-frequency LSI is mounted is disclosed in Japanese Patent Laid-Open Publication No. 2002-94247. The package includes a base board in which a multilayer wiring structure is formed on a core board, and semiconductor elements such as the high-frequency LSI are formed on the base board. The multilayer wiring structure is one in which the core board, a copper foil with dielectric resin layer, and the like are laminated.

However, the related art described in the above reference is susceptible to improvement in the following points.

When a device forming board such as the above base board includes a multilayer dielectric film, in the dielectric resin layers of the multilayer dielectric film, sometimes there is a difference in thickness, linear expansion coefficient, or the like. Therefore, in a heat cycle during manufacturing the semiconductor apparatus or during use, sometimes there are differences in expansion and contraction levels of the dielectric resin layers of the multilayer dielectric film.

As a result, sometimes a decrease in adhesion properties between dielectric resin layers in the multilayer dielectric film or delamination is caused to reduce yield. Further, because warp of the device mounting board is caused, sometimes position accuracy is decreased and the yield is reduced when the semiconductor device is connected by a connecting method such as flip chip connection and wire bonding connection.

### SUMMARY OF THE INVENTION

In view of the foregoing, an object of the invention is to stably provide a device mounting board which has excellent reliability and heat-resistant properties.

Another object of the invention is to provide a device mounting board having excellent reliability and heat-resistant properties, in which position accuracy is favorably maintained when the semiconductor device is mounted.

The invention provides a method of manufacturing a device mounting board for mounting a device, the device mounting board manufacturing method including the steps of forming a first lamination film including a plurality of dielectric layers on one surface of a base material; and forming a second lamination film including the plurality of dielectric layers on the other surface of the base material, wherein the step of forming the first lamination film includes a step of forming the dielectric layer containing a first cardo type polymer by bonding a material film containing the first cardo type polymer, as the dielectric layer containing the first cardo type polymer being any one of the dielectric layers the second and after, counted from the base material side, and the step of forming the second lamination film includes a step of forming the dielectric layer containing a second cardo type polymer by bonding a material film containing the second cardo type polymer, as the dielectric layer containing the second cardo type polymer being any one of the dielectric layers the second and after, counted from the base material side.

In the cardo type polymer, because a bulky substituent group obstructs movement of a main chain, the cardo type polymer is excellent for heat-resistant properties and mechanical strength. Because the material containing the cardo type polymer contains the cardo type polymer having high glass transition temperature, the material containing the cardo type polymer can contain other components having high flow properties. Therefore, the material containing the cardo type polymer has characteristics in which moderate flexibility is imparted by heating the material containing the cardo type polymer. When a film containing the cardo type polymer is bonded to form the dielectric film, because little air is involved during the bonding, the dielectric film can stably be manufactured. The manufactured dielectric film is excellent in the heat-resistant properties and the mechanical strength. Further, in the dielectric film, the number of voids is decreased and unevenness is improved. According to the method of present invention, the device mounting board which is excellent in reliability and the heat-resistant properties can stably manufactured.

The invention provides a device mounting board on which a device is mounted, the device mounting board including a base material; a first lamination film including a plurality of dielectric layers on one surface of the base material; and a second lamination film including the plurality of dielectric layers on the other surface of the base material, wherein, in the first lamination layer, any one of the dielectric layers the second and after, counted from the base material side is the dielectric layer containing a first cardo type polymer, the dielectric layer containing the first cardo type polymer being formed by bonding a material film containing the first cardo type polymer, and, in the second lamination layer, any one of the dielectric layers the second and after, counted from the base material side is the dielectric layer containing a second cardo type polymer, the dielectric layer containing the second cardo type polymer being formed by bonding a material film containing the second cardo type polymer.

In the cardo type polymer, because the bulky substituent group obstructs the movement of the main chain, the cardo type polymer is excellent in the heat-resistant properties and the mechanical strength and the cardo type polymer has the linear expansion coefficient. Therefore, in the heat cycle, the decrease in adhesion properties between dielectric resin layers in the multilayer resin film and the delamination are suppressed in the device mounting board. As a result, the device mounting board which is excellent in reliability and the heat-resistant properties can stably provided.

Although the configurations of the invention are described, that the configurations are arbitrarily combined is effective in a mode of the invention. That expression of the invention is converted into the device mounting board manufacturing method or the semiconductor device including the device mounting board is also effective in the mode of the invention.

In the invention, the term of the device mounting board shall mean the board for mounting the semiconductor devices such as the LSI chip and the IC chip, the active elements such as a transistor and a diode, and the passive elements such as a resistor, a coil, and a capacitor. An interposer board in the later-mentioned ISB (registered trademark) structure can be cited as an example of the device mounting board. It is possible that the device mounting board includes a core board having rigidity like a silicon substrate. It is also possible that the device mounting board does not have the core board, but has a coreless structure including the multilayer dielectric film formed by the dielectric resin films.

In the invention, the term of an external terminal shall mean the terminal which can be connected to the external element, the board, and the like. The electrode pad and the solder ball can be cited as an example of the external terminal. However, the external terminal is not limited to the above examples, and the external terminal may include a part of pieces of wiring which can be connected to the external element, the board, and the like and a part of other conductive members.

In the case where the semiconductor devices such as the LSI chip and the IC chip are mounted on the surface of device mounting board, the connection can be achieved by the flip chip connection or the wire bonding connection. In any connecting method, the semiconductor device can be mounted with high position accuracy using the device mounting board.

### BRIEF DESCRIPTION OF THE DRAWINGS

FIG. 1 is a view for explaining a structure of ISB (REGISTERED TRADEMARK);

FIG. 2A is a view for explaining a process of manufacturing ISB (REGISTERED TRADEMARK), and FIG. 2B is a view for explaining a process of manufacturing BGA;

FIGS. 3A and 3B are a process sectional view showing a procedure of manufacturing a device mounting board in a first embodiment;

FIGS. 4A to 4C are a process sectional view showing the procedure of manufacturing the device mounting board in the first embodiment;

FIGS. 5A and 5B are a process sectional view showing the procedure of manufacturing the device mounting board in the first embodiment;

FIGS. 6A to 6C are a process sectional view showing the procedure of manufacturing the device mounting board in the first embodiment;

FIGS. 7A and 7B are a process sectional view showing the procedure of manufacturing the device mounting board in the first embodiment;

FIGS. 8A to 8C are a process sectional view showing the procedure of manufacturing the device mounting board in the first embodiment;

FIGS. 9A and 9B are a process sectional view showing the procedure of manufacturing the device mounting board in the first embodiment;

FIGS. 10A and 10B are a process sectional view showing the procedure of manufacturing the device mounting board in the first embodiment;

FIG. 11 is a process sectional view showing a detail process of performing simultaneous double-side press work in the procedure of manufacturing the device mounting board in the first embodiment;

FIG. 12 is a process sectional view showing a detail process of performing double-side press work in each side in the procedure of manufacturing the device mounting board in the first embodiment;

FIG. 13 is a process sectional view showing the detail process of performing double-side press work in each side in the procedure of manufacturing the device mounting board in the first embodiment;

FIGS. 14A and 14B are a process sectional view showing the procedure of manufacturing the usual device mounting board when a photoimageable solder resist film is applied by a spin coat method;

FIG. 15 is a view showing a schematic configuration of the conventional BGA;

FIGS. 16A to 16D are a sectional view schematically showing various semiconductor apparatuses formed by mounting a semiconductor device on the device mounting board in the first embodiment;

FIGS. 17A and 17B are a process sectional view showing the procedure of manufacturing the device mounting board in Example 1;

FIGS. 18A to 18C are a process sectional view showing the procedure of manufacturing the device mounting board in Example 1;

FIGS. 19A and 19B are a process sectional view showing the procedure of manufacturing the device mounting board in Example 1;

FIGS. 20A to 20C are a process sectional view showing the procedure of manufacturing the device mounting board in Example 1;

FIGS. 21A and 21B are a process sectional view showing the procedure of manufacturing the device mounting board in Example 1;

FIGS. 22A to 22C are a process sectional view showing the procedure of manufacturing the device mounting board in Example 1;

FIGS. 23A and 23B are a process sectional view showing the procedure of manufacturing the device mounting board in Example 1;

FIGS. 24A and 24B are a process sectional view showing the procedure of manufacturing the device mounting board in Example 1;

FIGS. 25A and 25B are a process sectional view showing the procedure of manufacturing the device mounting board when the usual photoimageable solder resist film is used;

FIGS. 26A to 26D are a sectional view schematically showing various semiconductor apparatuses formed by mounting the semiconductor device on the device mounting board in Example 1.

### DETAILED DESCRIPTION OF THE INVENTION

In the invention, it is possible that the process of forming the dielectric layer containing the above-mentioned first cardo type polymer by the bonding includes the process of bonding the material film containing the first cardo type polymer by the double-side press work, and the process of forming the dielectric layer containing the above-mentioned second cardo type polymer by the bonding includes the process of bonding the material film containing the first cardo type polymer by the double-side press work.

According to the above method, the manufacturing process is simplified because the bonding process is completed at one time. Further, interlayer adhesion properties between the dielectric layer containing the cardo type polymer and other dielectric layers are improved.

It is also possible that the process of forming the dielectric layer containing the first cardo type polymer by the bonding includes the process of forming the solder resist layer by bonding the material film containing the first cardo type polymer. It is also possible that the process of forming the dielectric layer containing the second cardo type polymer by the bonding includes the process of forming the solder resist layer by bonding the material film containing the second cardo type polymer.

The cardo type polymer can preferably be used as the solder resist film, because the cardo type polymer has an excellent resolution as mentioned later. Namely, the position accuracy of a solder ball forming hole can favorably be maintained when the solder ball is provided.

It is also possible that the process of forming the dielectric layer containing the first cardo type polymer by the bonding and the process of forming the dielectric layer containing the above-mentioned second cardo type polymer by the bonding include the process of bonding the material film containing the first cardo type polymer and the material film containing the second cardo type polymer by the simultaneous double-side press work.

According to the above method, the manufacturing process is simplified because the bonding process is completed at one time. Further, interlayer adhesion properties between the dielectric layer containing the cardo type polymer and other dielectric layers are improved. The warp of the device mounting board is suppressed because thermal histories of the upper first lamination film and the lower second lamination film become similar to each other.

It is possible that the cardo type polymer is one which is formed of a cross-linked polymer having a carboxyl group and an acrylate group in the same molecular chain.

According to the configuration, the above-mentioned cardo type polymer is the chemical-crosslink type polymer which has the carboxyl group having development characteristics and the acrylate group which is of a cross-linking group in the same molecular chain, and radical diffusion is difficult to occur because the cardo type polymer has a bulky substituent group in a main chain. Therefore, the cardo type polymer becomes the photo-setting polymer having the high resolution. In this case, when the polymer is heated or the polymer is irradiated with an ultraviolet ray (UV), the acrylate group is cross-linked to form an acrylic group.

In the dielectric layer containing the cardo type polymer, it is possible that a glass transition temperature ranges from 180° C. to 220° C.

According to the configuration, because the dielectric film having the excellent heat-resistant properties is stably obtained, the semiconductor apparatus having the excellent reliability under the high-temperature condition can be obtained.

In the dielectric layer containing the above-mentioned cardo type polymer, it is possible that a linear expansion coefficient ranges from 50 ppm/° C. to 80 ppm/° C.

It is possible that the dielectric layer containing the above-mentioned cardo type polymer contains a filling material such as filler and fiber. Granular or fibrous SiO₂ or SiN can be used as the filler. In this case, it is also possible to obtain the dielectric layer formed of a resin composition whose linear expansion coefficient is not more than 20 ppm/K.

According to the configuration, the semiconductor apparatus which is excellent in the reliability and the manufacturing stability can be obtained, because the dielectric film in which the decrease in adhesion properties to other members caused by a heat cycle is suppressed is stably obtained.

In the dielectric layer containing the above-mentioned cardo type polymer, when an alternating electric field is applied at a frequency of 1 MHz, it is possible that dielectric dissipation factor ranges from 0.001 to 0.04.

According to the configuration, the semiconductor apparatus having the excellent dielectric characteristics can be obtained on the whole, because the dielectric film has the excellent dielectric characteristics such as the high-frequency characteristics at first.

In the invention, the semiconductor apparatus which includes the device mounting board and the semiconductor device mounted on the device mounting board is also provided.

According to the configuration, the reliability is improved in mounting the semiconductor device, because the semiconductor device is bonded onto the device mounting board which is excellent in the reliability and the heat-resistant properties by the flip chip connection or the wire bonding connection.

It is preferable that the dielectric layer containing the cardo type polymer is one which the cardo type polymer is contained as a base material. For example, it is possible that the dielectric layer contains the cardo type polymer of not lower than 30 mass %, and it is particularly preferable that the dielectric layer contains the cardo type polymer of not lower than 50 mass %. When the dielectric layer contains the cardo type polymer in the above range, the various characteristics and properties above-mentioned can stably be realized.

Referring now to the accompanying drawings, preferred embodiments of the invention will be described. In all the drawings, the same constituent is indicated by the same reference numeral, and the description is neglected as appropriate.

First, an ISB structure used for the semiconductor apparatus of each later-mentioned embodiment will be described. ISB (Integrated System in Board; registered trademark) is a unique package which has developed by employees of the applicant. In packaging an electronic circuit mainly including a semiconductor bear chip, ISB is a unique coreless system in package in which a core (base material) for supporting circuit components while having a wiring pattern made of copper.

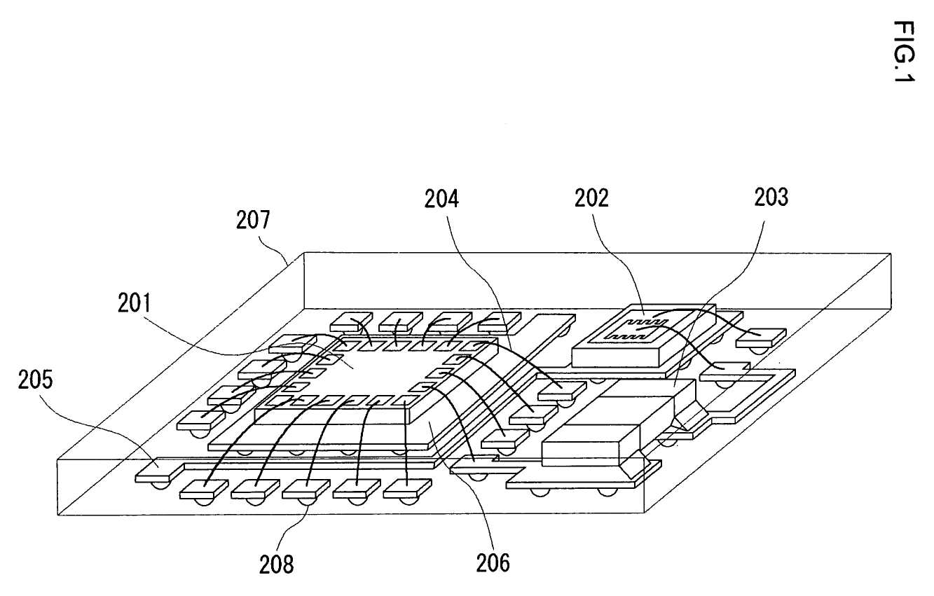

FIG. 1 is a schematic structural view showing an example of ISB. In order to easily see the whole structure of ISB, FIG. 1 shows only a single wiring layer. However, actually ISB has the structure in which the plurality of wiring layers are laminated. The ISB has the structure, in which an LSI bear chip 201, a transistor bear chip 202, and a chip capacitor 203 are connected by the wiring made of a copper pattern 205. The LSI bear chip 201 is electrically connected to extraction electrodes and the wiring by gold bonding wires 204. A conductive paste 206 is provided immediately below the LSI bear chip 201, and ISB is mounted on the printed circuit board through the conductive paste 206. The whole of ISB is sealed by a resin package 207 made of epoxy resin or the like.

The package has the following advantages:
(i) The mounting can be performed with no core, so that miniaturization and the decrease in thickness of the transistor, IC, and LSI can be realized.
(ii) The circuit can be formed of the transistor, the system LSI, the chip type capacitor, and the chip type resistor to perform the packaging, so that advanced SIP (System in Package) can be realized.
(iii) The current semiconductor devices can be combined, so that the system LSI can be developed within a short period of time.
(iv) The semiconductor bear chip is directly mounted on the copper material right under, so that good heat radiation characteristics can be obtained.
(v) The circuit wiring is made of the copper material, and the core material is not used, so that the circuit wiring has a low dielectric constant, which exerts the excellent performance in high-speed data transfer and a high-frequency circuit.
(vi) ISB package has the structure in which the electrode is embedded inside the package, so that particle contamination of the electrode material can be prevented from producing.
(vii) A package size can be freely selected, and an amount of waste material per one package becomes about one-tenth in comparison with a 64-pin SQFP package, so that environmental load can be reduced.
(viii) ISB is not a printed circuit board on which the components are simply mounted, but is the circuit board to which functions are added, so that the new-concept system configuration can be realized.
(ix) Pattern design of ISB is easily performed like the pattern design of the printed circuit board, so that engineers in an electronic-device assembly plant can design the pattern by themselves.

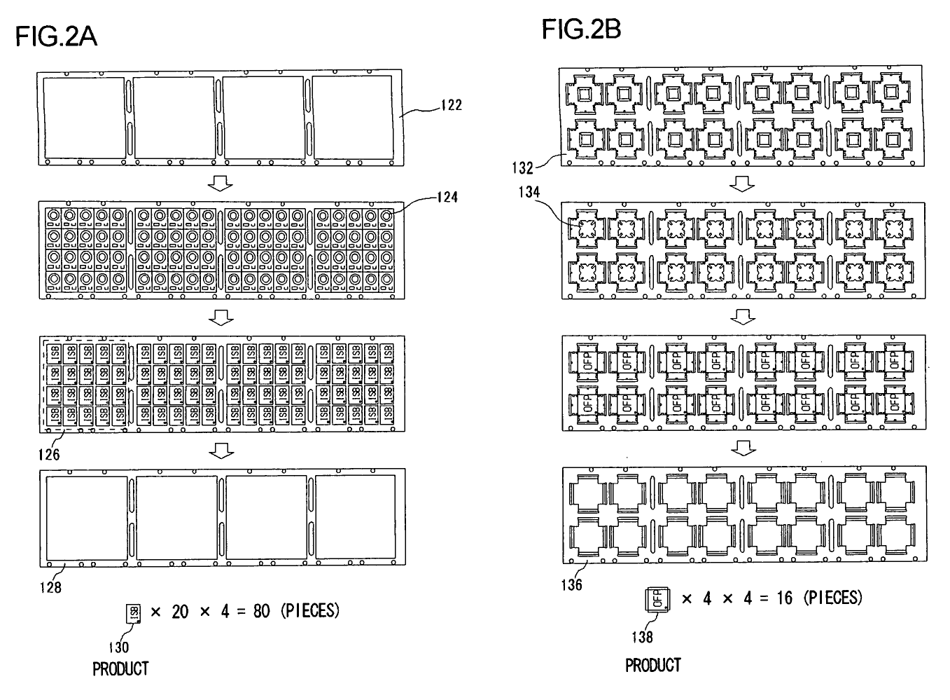

Then, the advantages of the process of manufacturing ISB will be described. FIG. 2A shows the process of manufacturing ISB, and FIG. 2B shows the process of manufacturing the conventional CSP, for comparison with each other.

FIG. 2B shows the process of manufacturing the conventional CSP. At first a frame 132 is formed on a base board, and a chip 134 is mounted in a device forming region which is separated in each frame. Then, the package is provided for each device by a thermosetting resin, and a product 138 is obtained by performing punching to each device using a punching die. In the punching which is of the final process, because the mold resin and the base board are simultaneously cut, sometimes surface roughening arises in a cutting plane. Further, sometimes the large amount of waste material 136 is produced after the punching, so that there is the problem in the environmental load.

FIG. 2A shows the process of manufacturing ISB. At first a frame 122 is provided on a metal foil, the wiring pattern is formed in each module forming region, and the circuit element such as LSI is mounted on the wiring pattern. Then, the packaging is performed to each module to obtain the frame 122 including a plurality of ISB basic blocks 126. Then, a product 130 is obtained by dicing the frame along a scribe region. After the packaging is performed, the metal foil which is of the base material is removed prior to a scribing process, so that only the resin layer is cut in the dicing in the scribing process. Therefore, the surface roughening is suppressed in the cutting plane, and accuracy of the dicing can be improved. In the process of manufacturing ISB, since only the small amount of waste material 128 is produced, there is the advantage in the environmental load.

<First Embodiment>

FIG. 10B is a sectional view showing the device mounting board having a four-layer ISB structure according to a first embodiment.

The device mounting board according to the first embodiment has the structure in which an dielectric resin film 312 and a photoimageable solder resist film 328 are sequentially laminated on an upper surface of a base material 302. The device mounting board also has the structure in which the dielectric resin film 312 and the photoimageable solder resist film 328 are sequentially laminated on a lower surface of the base material 302.

A through-hole 327 which pierces through the base material 302, the dielectric resin film 312, and the photoimageable solder resist film 328 is made.

A part of the piece of wiring made of a copper film 308, a part of the piece of wiring made of a copper film 320, a part of a via hole 311, and the like are embedded in the base material 302. A part of the piece of the wiring made of the copper film 308, a part of the piece of the wiring made of the copper film 320, wiring 309, a part of the via hole 311, a part of a via hole 323, and the like are embedded in the dielectric resin film 312. A part of the piece of the wiring made of the copper film 320, a part of the via hole 323, and the like are embedded in the photoimageable solder resist film 328. An opening 326 is provided in the photoimageable solder resist film 328.

The material used for the base material 302 is not particularly limited to a glass epoxy board, but any material having moderate rigidity can be used as the base material 302.

For example, a resin board and a ceramic board can be used as the base material 302. More specifically, the base material which is excellent in the high-frequency characteristics because of the low dielectric constant can be used. Namely, examples of the base material include polyphenyl ethylene (PPE), bismaleimide-triazine resins (BT-resin), polytetrafluoro-ethylene (registered trade name; Teflon), polyimide, liquid crystal polymer (LCP), polynorbornene (PNB), epoxy resins, acrylic resins, ceramics, a mixture of ceramic and an organic base material, and the like.

The resin material used for the dielectric resin film 312 is one which is softened by heating and by which the dielectric resin film 312 can be thinned to a certain level. Particularly the resin material, which has the low dielectric constant and the excellent high-frequency characteristics, can preferably be used.

It is possible that the dielectric resin film 312 contains the filling material such as the filler or the fiber. For example, the granular or fibrous SiO₂ or SiN can be used as the filler.

The photoimageable solder resist film 328 contains the cardo type polymer. The photoimageable solder resist film 328 is larger than the dielectric resin film 312 in a film thickness.

In the cardo type polymer, the bulky substituent group obstructs movement of the main chain, which results in the excellent mechanical strength, the excellent heat-resistant properties, and the low linear expansion coefficient. Therefore, in the heat cycle, the decrease in adhesion properties and delamination are suppressed among the base material 302, the dielectric resin film 312, and the photoimageable solder resist film 328. As a result, the reliability and the heat-resistant properties are improved in the device mounting board according to the first embodiment.

As mentioned later, because the photoimageable solder resist film 328 containing the cardo type polymer is formed by bonding the material film containing the cardo type polymer, little air is involved during the bonding, which allows the photoimageable solder resist film 328 to be stably obtained. The photoimageable solder resist film 328 is excellent in the heat-resistant properties and the mechanical strength. Further, in the photoimageable solder resist film 328, the number of voids is decreased, and unevenness is improved. Therefore, the reliability is improved when the semiconductor device is mounted on the device mounting board according to the first embodiment.

As mentioned later, because the cardo type polymer has the excellent resolution, the resolution is improved in the photoimageable solder resist film 328, and the cardo type polymer can preferably be used as the solder resist film. Namely, the position accuracy of the opening 326 used for the solder ball forming hole can favorably be maintained when the solder ball is provided in the photoimageable solder resist film 328.

The multilayer wiring structure including the wiring formed of copper film 308, the wiring formed of the copper film 320, the wiring 309, the via hole 311 and the via hole 323 is not limited to the copper wiring. For example, aluminum wiring, aluminum alloy wiring, copper alloy wiring, wire-bonded gold wiring, gold alloy wiring, the wiring formed by these pieces of wiring, and the like can also be used as the multilayer wiring structure.

It is also possible that active elements such as the transistor and the diode and passive elements such as the capacitor and the resistor are provided on the surface of or in the four-layer ISB structure. It is also possible that the active elements or the passive elements are connected to a multilayer wiring structure in the four-layer ISB and connected to the external conductive member through the via hole 323.

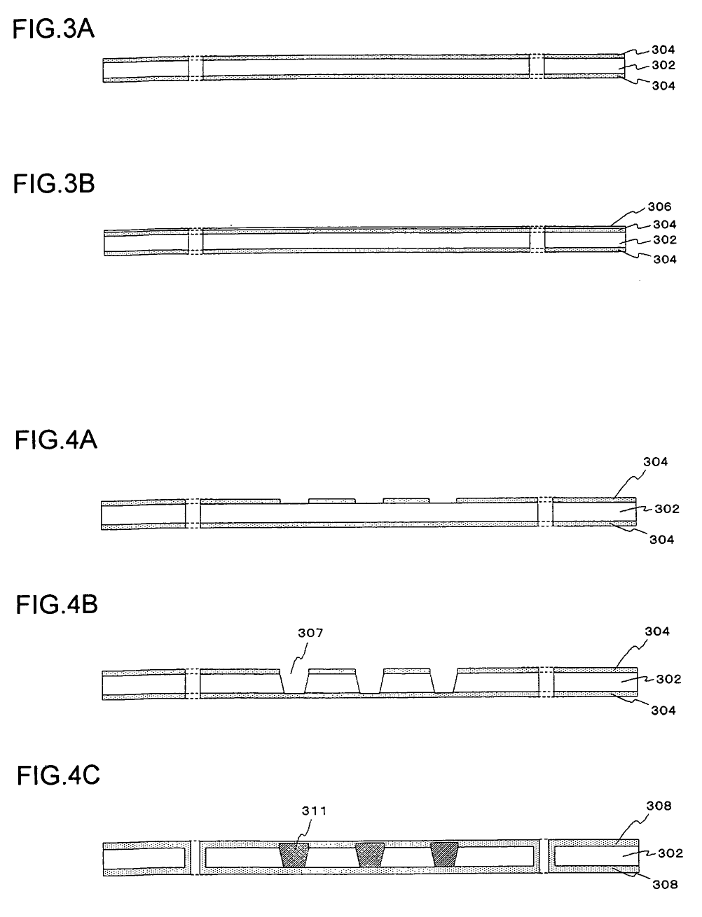

FIGS. 3A to 10B are a process sectional view showing a procedure of manufacturing the device mounting board including the four-layer ISB structure according to the first embodiment.

In manufacturing the device mounting board including the four-layer ISB structure according to the first embodiment, as shown in FIG. 3A, the base material 302 is prepared. The base material 302 is formed of the glass epoxy board or the like to which the copper foils 304 are bonded. Holes having diameters of about 150 nm are made by a drill in the copper foil 304. At this point, the thickness of the base material 302 ranges from about 37.5 μm to about 42.5 μm, and the thickness of the copper foil 304 ranges from about 10 μm to about 15 μm.

Instead of the copper foil 304, it is also possible to use an aluminum foil. Further, it is also possible to use a copper alloy foil, an aluminum alloy foil, or the like. Instead of the conductive member containing copper, it is also possible to use the conductive member containing other metals such as aluminum or these alloys.

Then, as shown in FIG. 3B, a photo-etching resist layer 306 is laminated on the upper surface of the copper foil 304.

Then, patterning of the photo-etching resist layer 306 is performed by exposing glass as a mask. Then, as shown in FIGS. 4A and 4B, using the photo-etching resist layer 306 as the mask, a via hole 307 having the diameter of about 100 nm is made by a chemical etching process with chemicals.

In the first embodiment, the chemical etching process with the chemicals is adopted as the method of forming the via hole 307. However, machining, dry etching with plasma, laser machining, and the like can also be used. The photo-etching resist layer 306 is removed after the etching.

Then, the inside of the via hole 307 is roughened and cleaned by a wet process. As shown in FIG. 4C, the via hole 307 is filled with the conductive material by electroless plating ready for a high aspect ratio and electrolytic plating to form a via hole 311, and the copper films 308 are formed over the surfaces.

For example, the via hole 311 can be formed in the following manner. After a thin film whose thickness ranges from about 0.5 to 1 μm is formed over the surface by the electroless copper plating, the film having the thickness of about 20 μm is formed by the electrolytic plating. Usually palladium is used as an electroless plating catalyst. In order to cause the electroless plating catalyst to adhere to the flexible dielectric resin, palladium is contained in an aqueous solution while being in a complex state, and the flexible dielectric base material is dipped to cause the palladium complex to adhere to the surface of the dielectric base material. In the state of things, nuclei for starting the plating onto the surface of the flexible dielectric base material can be formed by reducing the palladium complex to the metal palladium with a reducing agent.

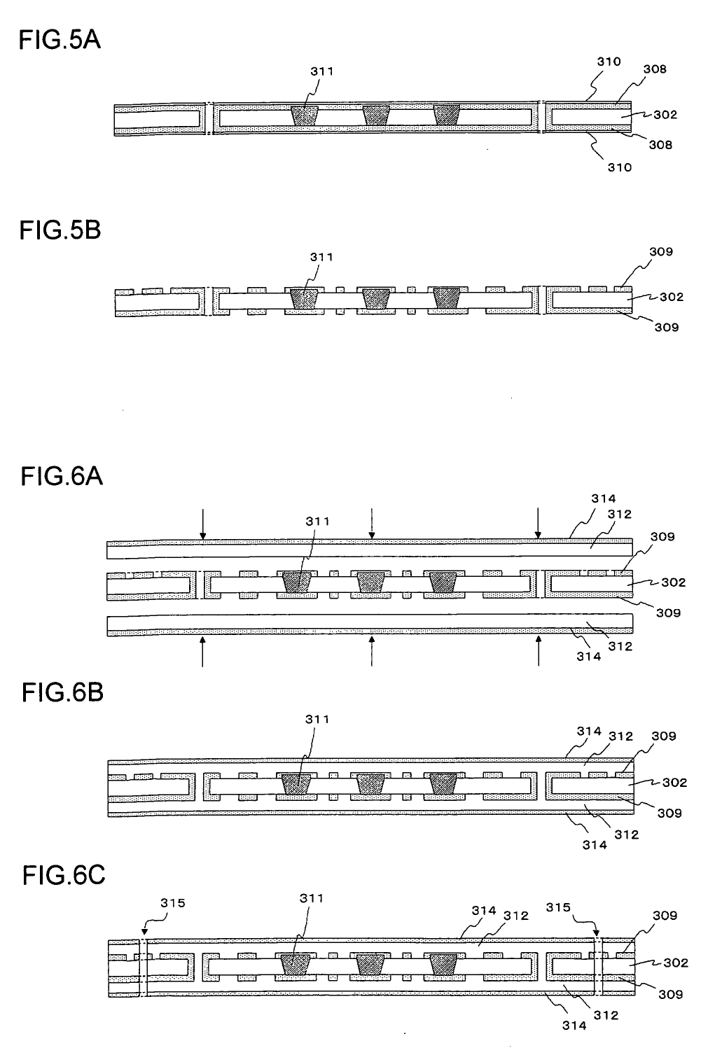

Then, as shown in FIG. 5A, photo-etching resist layers 310 are laminated onto the top surfaces of the upper and lower copper films 308. Then, the patterning is performed to the photo-etching resist layer 310 by performing the exposure with glass having a light-shielding range (not shown) as the mask.

As shown in FIG. 5B, the wiring 309 made of copper is formed by etching the copper film 308 formed of the copper plating layer using the photo-etching resist layer 310 as the mask. For example, the wiring pattern can be formed by spraying a point exposed from the resist with a chemical etching solution to remove the unnecessary copper plating. The photo-etching resist layer 310 is removed after the etching.

As shown in FIG. 6A, in order to form the dielectric resin film 312, resin films with copper foils 314 are bonded to the top surfaces of the upper wiring 309 and the lower wiring 309. The thickness of the resin film for forming the dielectric resin film 312 ranges from about 22.5 μm to about 27.5 μm, and the thickness of the copper foil 314 ranges from about 10 μm to about 15 μm.

In the bonding method, the dielectric resin film 312 with copper foil is caused to come into contact with the base material 302 and the wiring 309, and the base material 302 and the wiring 309 are fitted into the dielectric resin film 312. Then, as shown in FIG. 6B, the dielectric resin film 312 is heated in a vacuum or under a reduced pressure to bond the dielectric resin film 312 to the base material 302 and the wiring 309.

It is not always necessary that the dielectric resin film 312 is formed by the bonding. For example, it is possible that the dielectric resin film 312 is formed by applying and drying a liquid resin composition. It is possible that the dielectric resin film 312 is formed by the methods, such as a spin coating method, a curtain coating method, a roll coating method or a dip coating method, which are excellent for coating evenness, thickness control, and the like. In this case, the copper foil can be separately formed after the dielectric resin film 312 is formed.

As shown in FIG. 6C, the copper foil 314 is irradiated with an X-ray to make holes 315 which pierce through the copper foil 314, the dielectric resin film 312, the wiring 309, and the base material 302. Alternatively, it is possible that the holes 315 are made by laser irradiation or drilling.

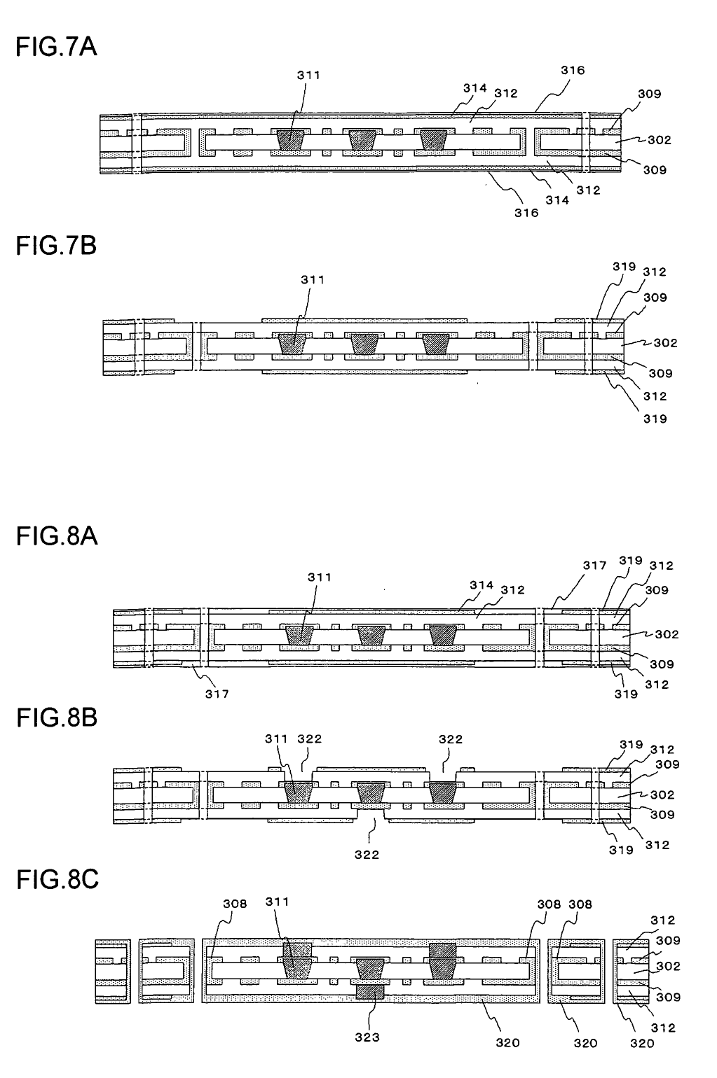

As shown in FIG. 7A, photo-etching resist layers 316 are laminated on the top surfaces of the upper and lower copper foils 314. Then, the patterning of the photo-etching resist layer 316 is performed by performing the exposure with the glass having the light-shielding range (not shown) as the mask.

As shown in FIG. 7B, wiring 319 is formed by etching the copper foil 314 with the photo-etching resist layer 316 as the mask. For example, the wiring pattern can be formed by spraying a point exposed from the resist with a chemical etching solution to remove the unnecessary copper foil. The photo-etching resist layer 316 is removed after the etching.

As shown in FIG. 8A, a photo-etching resist layer 317 is laminated onto the top surfaces of the upper wiring 319 and the lower wiring 319. Then, the patterning of the photo-etching resist layer 317 is performed by performing the exposure with the glass having the light-shielding range (not shown) as the mask.

As shown in FIG. 8B, the patterning is performed to the wiring 319 and the dielectric resin film 312 with the photo-etching resist layer 317 as the mask to make a via hole 322 having the diameter of about 150 nm. The photo-etching resist layer 317 is removed after the etching.

In the first embodiment, the chemical etching process with the chemicals is adopted as the method of forming the via hole 322. However, the machining, the dry etching with plasma, the laser machining, and the like can also be used.

As shown in FIG. 8C, the inside of the via hole 322 is roughened and washed by the wet process. Then, the via hole 322 is filled with the conductive material by the electroless plating ready for the high aspect ratio and the electrolytic plating, and after forming the via hole 323, copper films 320 are formed over the surfaces.

For example, the via hole 323 can be formed in the following manner. After the thin film whose thickness ranges from about 0.5 to about 1 μm is formed over the surface by the electroless copper plating, the film having the thickness of about 20 μm is formed by the electrolytic plating. Usually palladium is used as the electroless plating catalyst. In order to cause the electroless plating catalyst to adhere to the flexible dielectric resin, palladium is contained in an aqueous solution while being in the complex state, and the flexible dielectric base material is dipped to cause the palladium complex to adhere to the surface of the dielectric base material. In the state of things, the nuclei for starting the plating onto the surface of the flexible dielectric base material can be formed by reducing the palladium complex to the metal palladium with the reducing agent.

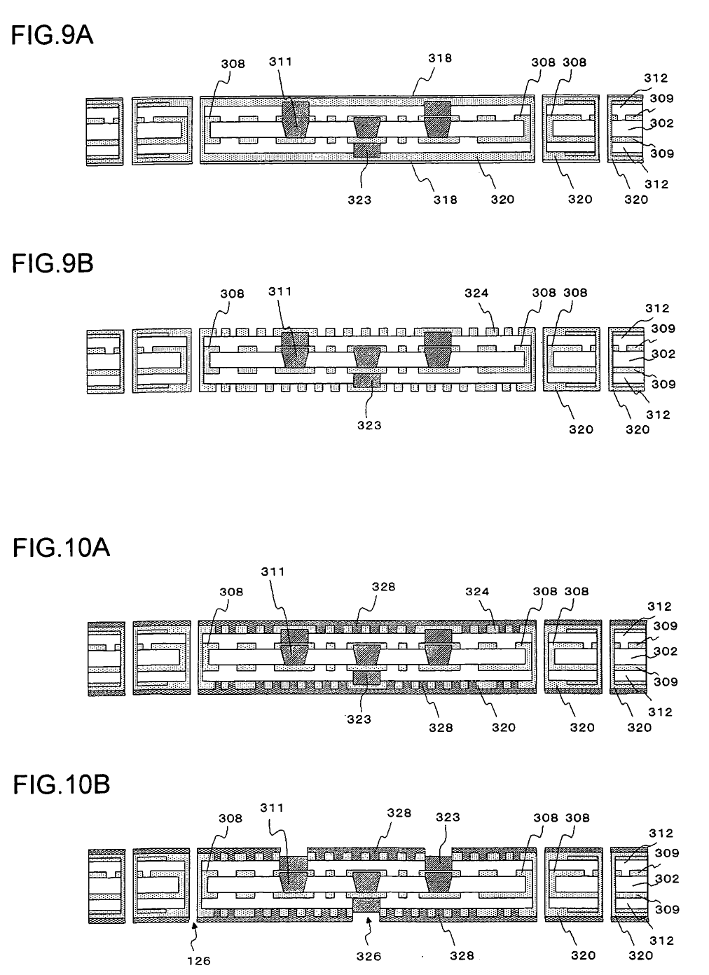

Then, as shown in FIG. 9A, photo-etching resist layers 318 are laminated onto the top surfaces of the upper and lower copper films 320. Then, the patterning is performed to the photo-etching resist layer 318 by per forming the exposure with glass having the light-shielding range (not shown) as the mask.

As shown in FIG. 9B, wiring 324 made of copper is formed by etching the copper film 320 using the photo-etching resist layer 318 as the mask. For example, the wiring pattern can be formed by spraying the point exposed from the resist with the chemical etching solution to remove the unnecessary copper foil.

As shown in FIG. 10A, the photoimageable solder resist layers 328 containing the cardo type polymers are laminated onto the top surfaces of the upper wiring 324 and the lower wiring 324 by the later-mentioned bonding method.

As shown in FIG. 10B, the patterning is performed to the photoimageable solder resist layer 328 by performing the exposure with the glass having the light-shielding range as the mask. Then, the wiring 324 is etched using the photoimageable solder resist layer 328 as the mask so that the via hole 323 formed inside the via hole 322 is exposed, and the opening 326 having the diameter of about 150 nm is formed.

In the first embodiment, the chemical etching process with the chemicals is adopted as the method of forming the opening 326. However, the machining, the dry etching with plasma, the laser machining, and the like can also be used. Then, the gold plating is performed to the exposed via hole 323 (not shown). Alternatively, it is also possible that the solder ball is directly formed in the exposed via hole 323.

For the sake of convenience, the description of the semiconductor device is neglected. However, usually the semiconductor device such as the LIS chip and the IC chip is mounted on the surface of the four-layer ISB structure by the flip chip connection or the wire bonding connection.

The method of bonding the photoimageable solder resist layers 328 containing the cardo type polymers onto the top surfaces of the upper wiring 324 and the lower wiring 324, shown in FIG. 10A, will be described in detail. The method of bonding the photoimageable solder resist layers 328 containing the cardo type polymers onto the top surfaces of the upper wiring 324 and the lower wiring 324 is not particularly limited, but any method in which the bonding is performed by applying constant pressure can be adopted. The method of performing the simultaneous bonding of the double sides using a double-side press machine and the method of sequentially performing the bonding in each side using the double-side press machine can be cited as examples of the bonding method.

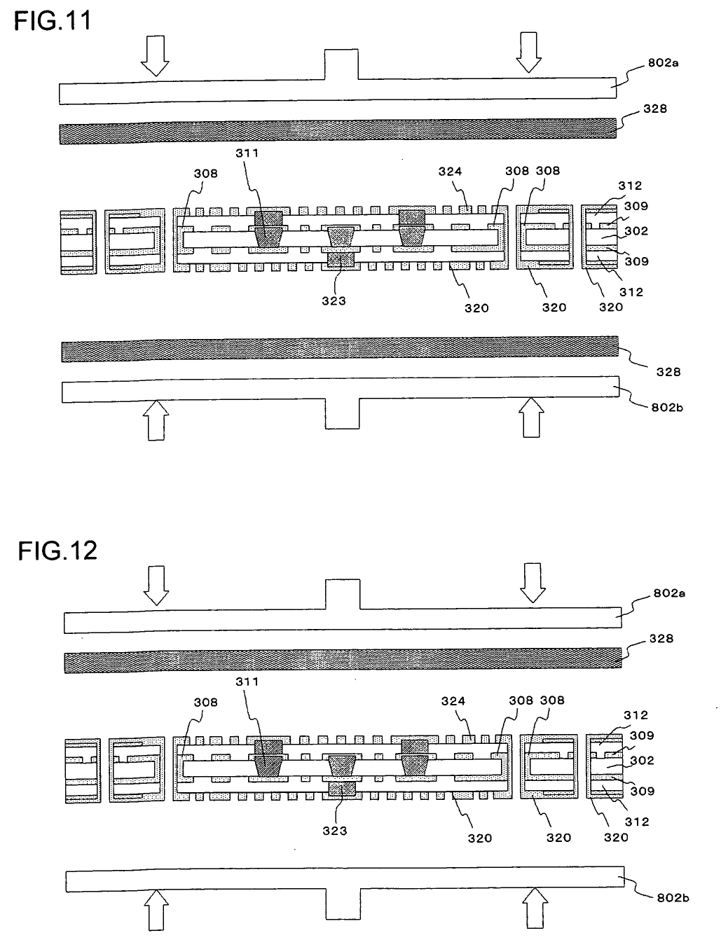

FIG. 11 is a process sectional view showing the detail process of performing the simultaneous double-side press work in the procedure of manufacturing the device mounting board in the first embodiment.

In this case, the photoimageable solder resist layers 328 containing the cardo type polymer are arranged on the both surfaces of the four-layer ISB board. Then, the photoimageable solder resist layers 328 containing the cardo type polymer are simultaneously bonded from the upper and lower sides to the surfaces using the double-side press 802a and 802b. Therefore, the photoimageable solder resist layers 328 containing the cardo type polymer are simultaneously bonded to the top surfaces of the upper wiring 324 and the lower wiring 324, which are provided on the both surface of the four-layer ISB board.

At this point, it is necessary that the bonding conditions are appropriately adjusted according to the structure of the four-layer ISB board and the composition of the photoimageable solder resist layer 328. For example, the temperature is set to 110° C., the time is set to the range from 1 to 2 minutes, and the pressure is set to about 2 atmospheres.

According to the method, in the cardo type polymer, since the bulky substituent group obstructs the movement of the main chain, the cardo type polymer is excellent in the heat-resistant properties and the mechanical strength. In the material containing the cardo type polymer, since the cardo type polymer has the high glass transition temperature, the material containing the cardo type polymer can contain a large amount of other component having the high flow properties. Therefore, the material containing the cardo type polymer has the characteristics that the flexibility becomes a proper level by the heating. When the film containing the cardo type polymer is bonded to form the photoimageable solder resist layer 328, since the little air is involved during the bonding, the photoimageable solder resist layer 328 can stably be obtained. The photoimageable solder resist layer 328 is excellent in the heat-resistant properties and the mechanical strength. Further in the photoimageable solder resist layer 328, the number of voids is decreased, and the unevenness is improved. Therefore, according to the method, the device mounting board which is excellent in the reliability and the heat-resistant properties can stably be manufactured.

Since the simultaneous double-side bonding is performed to the photoimageable solder resist layers 328 containing the cardo type polymer, the bonding process is completed at one time, which simplifies the manufacturing process. Further, the interlayer adhesion properties between the photoimageable solder resist layer 328 containing the cardo type polymer and the dielectric resin layer 312 and the like are improved. In this case, the warp of the device mounting board is suppressed, because thermal histories of the dielectric resin film 312 and the photoimageable solder resist layers 328 on the upper side of the four-layer ISB board and the dielectric resin film 312 and the photoimageable solder resist layers 328 on the lower side become similar to each other.

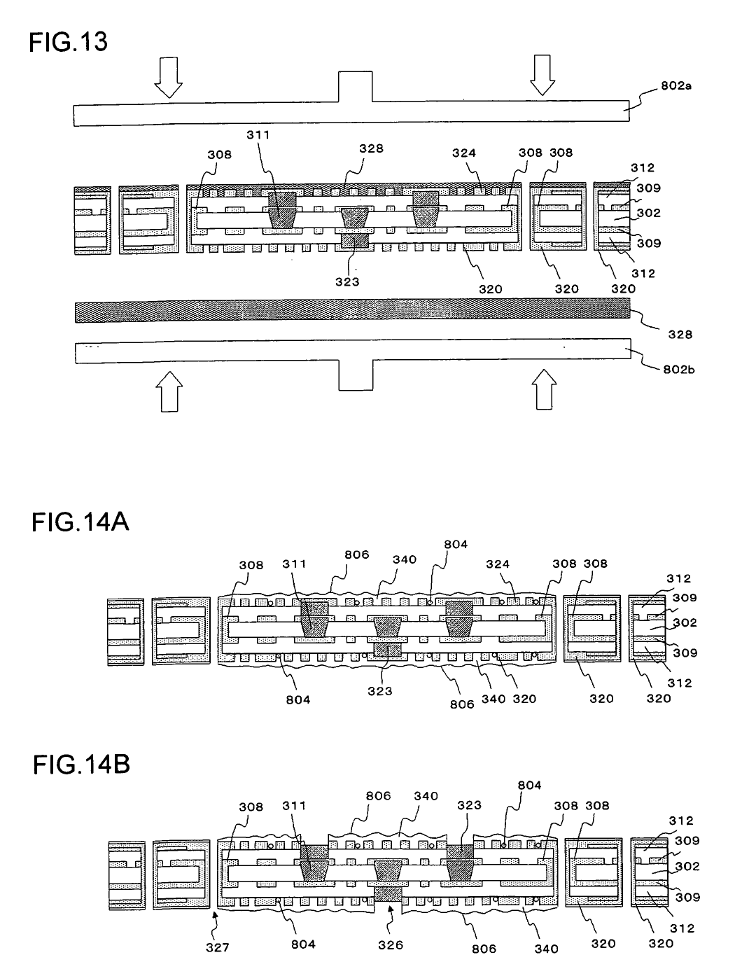

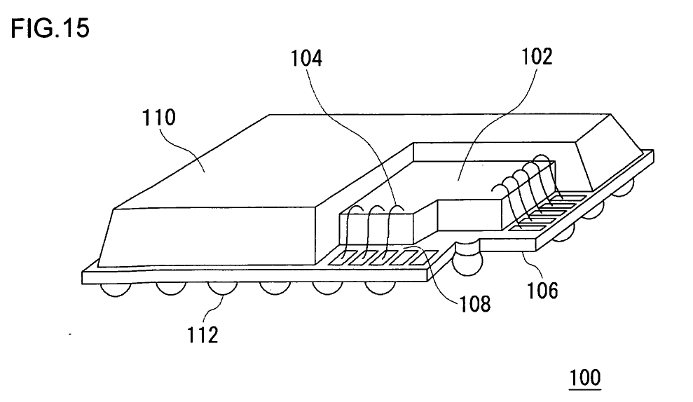

FIGS. 12 and 13 are a process sectional view showing the detail process of sequentially performing the double-side press work in each side in the procedure of manufacturing the drive mounting board in the first embodiment.

In this case, the photoimageable solder resist layer 328 containing the cardo type polymer is arranged on the surface on one side of the four-layer ISB board. Then, the photoimageable solder resist layers 328 and the four-layer ISB board are bonded to each other using the double-side press 802a and 802b. Therefore, the photoimageable solder resist layers 328 containing the cardo type polymer is bonded to the top surface of the wiring 324 provided on one side of the four-layer ISB board.

At this point, it is necessary that the bonding conditions are appropriately adjusted according to the composition and the structure of the four-layer ISB board and the composition of the photoimageable solder resist layer 328. For example, the temperature is set to 110° C., the time is set to the range from 1 to 2 minutes, and the pressure is set to about 2 atmospheres.

Then, the photoimageable solder resist layer 328 containing the cardo type polymer is arranged on the surface on the other side of the four-layer ISB board. Then, the photoimageable solder resist layers 328 and the four-layer ISB board are bonded to each other from the upper and lower sides using the double-side press 802a and 802b. Therefore, the photoimageable solder resist layers 328 containing the cardo type polymer is bonded to the surface of the wiring 324 provided on the other side of the four-layer ISB board.

According to the method, when the film containing the cardo type polymer is bonded to form the photoimageable solder resist layer 328, since the little air is involved during the bonding of any surface, the photoimageable solder resist layer 328 can also stably be formed. The photoimageable solder resist layer 328 is excellent in the heat-resistant properties and the mechanical strength. Further in the photoimageable solder resist layer 328, the number of voids is decreased, and the unevenness is improved. Therefore, according to the method, the device mounting board which is excellent in the reliability and the heat-resistant properties can also stably be manufactured.

Since the single-side bonding is performed to the photoimageable solder resist layer 328 containing the cardo type polymer, the bonding process is completed at two times, which simplifies the manufacturing process. Further, the interlayer adhesion properties between the photoimageable solder resist layer 328 containing the cardo type polymer and the dielectric resin layer 312 and the like are improved.

For the sake of comparison, the manufacturing procedure with the conventional photoimageable solder resist film will de described. In the case of the use of the conventional photoimageable solder resist, the manufacturing procedure shown in FIGS. 14A and 14B is performed after the manufacturing procedure shown in FIGS. 3A to 9B.

Namely, in the case of the use of the conventional photoimageable solder resist film, after the manufacturing process shown in FIG. 9B, the conventional photoimageable solder resist solutions are applied to the top surfaces of the upper wiring 324 and the lower wiring 324 by the spin coating method or the like and dried to form a conventional photoimageable solder resist layer 340 as shown in FIG. 14A.

As shown in FIG. 11B, the patterning is performed to the conventional photoimageable solder resist layer 340 by performing the exposure with the glass having the light-shielding range as the mask. Then, the wiring 324 is etched using the conventional photoimageable solder resist layer 340 as the mask so that the via hole 323 formed inside the via hole 322 is exposed, and the opening 326 having the diameter of about 150 nm is formed.

In the manufacturing procedure with the conventional photoimageable solder resist film, the chemical etching process with the chemicals is adopted as the method of forming the opening 326. However, the machining, the dry etching with plasma, the laser machining, and the like can also be used. Then, the gold plating is performed to the exposed via hole 323 (not shown). It is also possible that the solder ball is directly formed in the exposed via hole 323.

In this case, since the conventional photoimageable solder resist layers 340 are formed on the top surfaces of the upper wiring 324 and the lower wiring 324 by applying and drying the conventional photoimageable solder resist solution by the spin coating method or the like, sometimes the air is involved during the application or the drying by the spin coating method or the like, which results in the generation of avoid 804 and unevenness 806.

On the contrary, in the first embodiment, when the film containing the cardo type polymer is bonded to form the photoimageable solder resist layer 328, as shown in FIGS. 11A and 10B, since the little air is involved during the bonding at the surfaces on both the sides, the photoimageable solder resist layer 328 can stably be formed. The photoimageable solder resist layer 328 is excellent in the heat-resistant properties and the mechanical strength. Further, in the photoimageable solder resist layer 328, the number of voids is decreased and the unevenness is improved.

The effect of using the dielectric resin film made of the resin material containing the cardo type polymer, which is obtained by adding a predetermined modifying agent, in the first embodiment will be described below.

In the first embodiment, it is possible that both the negative type resist film and the positive type resist film are used as the photoimageable solder resist film 328. However, in the case where the cardo type polymer has the carboxyl group and the acrylate group in the same molecular chain, usually the negative type resist is used as the photoimageable solder resist film 328.

As used herein the term of the negative type photoimageable solder resist 328 shall mean the dielectric coating film in which a structural change is made only in the photosensitized portion in order not to be dissolved in solvent.

Because the photoimageable solder resist film 328 is used during the soldering, excellent durability such as the heat-resistant properties and high elasticity are required for the photoimageable solder resist film 328. In the first embodiment, because the negative type photoimageable solder resist film 328 containing the particular polymer described later is used, the photoimageable solder resist film 328 has the excellent durability such as the heat-resistant properties and the high elasticity.

The lamination type photoimageable solder resist film 328 is not the photoimageable solder resist which is formed by applying the usual stock solution, but the lamination type photoimageable solder resist film 328 which is formed by bonding the photoimageable solder resist thin film. The photoimageable solder resist film 328 is bonded to the semiconductor substrate and the like under the proper temperature and pressure conditions while being softened to a certain level.

The thickness of material film of the lamination type photoimageable solder resist film 328 before bonding is not particularly limited. However, for example, it is possible that the thickness is not lower than 10 μm, and particularly it is preferable that the thickness is not lower than 20 μm. Further, the thickness of the lamination type photoimageable solder resist film 328 obtained by bonding the material film can be made more than 15 μm for example, and particularly it is preferable that the thickness is not lower than 25 μm. When the thickness of the material film or the lamination type photoimageable solder resist film 328 exists in the above range, the mechanical strength, the reliability, and productivity are improved.

For example, it is possible that the thickness of material film of the lamination type photoimageable solder resist film 328 before bonding is not more than 150 μm, and particularly it is preferable that the thickness is not more than 100 μm. Further, the thickness of the lamination type photoimageable solder resist film 328 obtained by bonding the material film can be made not more than 150 μm, and particularly it is preferable that the thickness is not more than 100 μm. When the thickness of the material film or the lamination type photoimageable solder resist film 328 exists in the above range, insulating properties and flatness of board surface are improved in the photoimageable solder resist film 328.

Even if the lamination type photoimageable solder resist film 328 is thick, when the thickness of the lamination type photoimageable solder resist film 328 exists in the above-mentioned range, the use of the material film containing the later-mentioned cardo type polymer which is excellent in resolution improves workability during a process of curing the photoimageable solder resist 328 by UV irradiation.

It is possible that the thickness of the photoimageable solder resist layer 328 is not lower than 5% of the whole thickness of the device mounting board, and it is particularly preferable that the thickness of the photoimageable solder resist layer 328 is not lower than 10% of the whole thickness of the device mounting board. When the relative thickness of the lamination type photoimageable solder resist film 328 exists in the above range, the insulating properties and the mechanical strength are improved.

It is possible that the thickness of the photoimageable solder resist layer 328 is not more than 50% with respect to the whole thickness of the device mounting board, and it is particularly preferable that the thickness of the photoimageable solder resist layer 328 is not more than 40% with respect to the whole thickness of the device mounting board. When the relative thickness of the lamination type photoimageable solder resist film 328 exists in the above range, the pressure can be reduced during the bonding of the lamination type photoimageable solder resist film 328, and the stress applied to the whole of device mounting board can also be suppressed.

Even if the lamination type photoimageable solder resist film 328 is thickened, when the thickness of the lamination type photoimageable solder resist film 328 exists in the above-mentioned range, the use of the material film containing the later-mentioned cardo type polymer which is excellent in the resolution improves workability during a process of curing the photoimageable solder resist 328 by the UV irradiation.

In the lamination type photoimageable solder resist film 328 containing the cardo type polymer, the later-mentioned desirable characteristics are imparted by curing the lamination type photoimageable solder resist film 328 in a post-baking process under proper conditions aside from the above-mentioned exposure and development process in general.

In order to realize the lamination type photoimageable solder resist 328 whose thickness is larger than that of the conventional lamination type photoimageable solder resist, it is effective to use the cardo type polymer having the later-mentioned particular structure. Because the later-mentioned cardo type polymer has the excellent workability, the material film having the excellent insulating properties can be formed in thickness thicker than the conventional material.

It is possible that the lamination type photoimageable solder resist 328 contains the cardo type polymer. The cardo type polymer is a general term for the polymer having the structure in which a cyclic group is directly bonded to the polymer main chain as shown in Chemical Formula I.

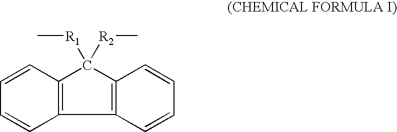

Wherein, R₁ and R₂ express bivalent groups such as analkylene group and a group containing an aromatic ring.

Namely, the cardo type polymer means the polymer having the structure in which the bulky substituent group containing a quaternary carbon atom is substantially perpendicular to the main chain.

It is possible that cyclic portion includes either a saturated bond or an unsaturated bond. In addition to the carbon atom, it is possible that cyclic portion includes atoms such as a nitrogen atom, an oxygen atom, a sulfur atom, and a phosphorus atom. It is possible that the cyclic portion is formed in a polycycle or a condensed ring. Further, it is possible that the cyclic portion is bonded to and moreover cross-linked with other carbon chains.

As shown in Chemical Formula II, an example of the bulky substituent group includes the cyclic group such as a fluorenyl group which includes the fused ring having the structure in which six-membered rings are bonded to both sides of a five-membered ring and the remaining one carbon atom of the five-membered ring is bonded to the main chain.
[Chemical Formula II]

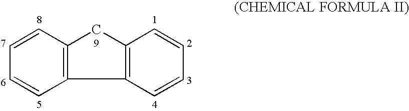

The fluorenyl group is one in which the 9-position carbon atom of fluorene is dehydrogenized. In the cardo type polymer, as shown in Chemical Formula I, the fluorenyl group is bonded to the carbon atom of the alkyl group which is of the main chain at the position of the dehydrogenized carbon atom.

Since the cardo type polymer is one which has the above-mentioned structure, the cardo type polymer has the following effects:
(1) Rotation constraint of polymer main chain.
(2) Conformation control of main chain and side chain.
(3) Packing obstruction between molecules.
(4) Increase in aromaticity by introducing aromatic substituent group to side chain.

Accordingly, the cardo type polymer has the features such as the high heat-resistant properties, solvent solubility, high transparency, high refractive index, low birefringence, and higher gas permeability.

The material film of the lamination type photoimageable solder resist film 328 before bonding can be formed in the thick film while the void and the unevenness are prevented from producing by using the cardo type polymer and a predetermined additive. The material film containing the cardo type polymer is easily softened by heating, so that the material film containing the cardo type polymer has good embedding properties. Similarly, the small number of voids exists in the lamination type photoimageable solder resist film 328 in the bonded device mounting board, and the little unevenness exists in the lamination type photoimageable solder resist film 328. Therefore, the lamination type photoimageable solder resist film 328 having the small number of voids secures the accurate film thickness.

It is also possible that the cardo type polymer is one which is formed of the cross-linked polymer having the carboxyl group and the acrylate group in the same molecular chain. Conventionally, a blend of a carboxyl group oligomer having development properties and polyfunctional acryl is used as the general photosensitive varnish. However, the general photosensitive varnish still has room for improvement in the resolution. When the cardo type polymer formed of the cross-linked polymer having the carboxyl group and the acrylate group in the same molecular chain is used instead of the general photosensitive varnish, the cardo type polymer has the carboxyl group having the development properties and the acrylate group which is of the crosslink properties in the same molecular chain, and the cardo type polymer also has the bulky substituent group in the main chain, so that the radical diffusion is difficult to occur. Therefore, in the photoimageable solder resist film 328 containing the cardo type polymer, there is the advantage that the resolution is improved.

It is desirable that the photoimageable solder resist film 328 formed of the resin film containing the cardo type polymer (referred to as cardo type polymer contained resin film) satisfies the following physical properties. The following physical properties are the value for the resin portion which does not include the filler and the like, and the physical properties can be appropriately adjusted by adding the filler and the like.

In the cardo type polymer contained resin film, it is possible that the glass transition temperature (Tg) is not lower than 180° C., and it is particularly preferable that the glass transition temperature (Tg) is not lower than 190° C. When the glass transition temperature (Tg) exists in the above range, the heat-resistant properties are improved in the cardo type polymer contained resin film.

In the cardo type polymer contained resin film, it is possible that the glass transition temperature (Tg) is not more than 220° C., and it is particularly preferable that the glass transition temperature (Tg) is not more than 210° C. When the glass transition temperature (Tg) exists in the above range, the cardo type polymer contained resin film can stably be produced by the usual manufacturing method. The glass transition temperature can be measured by dynamic viscoelasticity measurement (DMA) of a bulk sample for example.

In the range which is not more than the glass transition temperature of the cardo type polymer contained resin film, it is possible that the linear expansion coefficient (CTE) is not more than 80 ppm/° C. for example, and it is particularly preferable that the linear expansion coefficient is not more than 75 ppm/° C. When the linear expansion coefficient exists in the above range, the adhesion properties between the cardo type polymer contained resin film and other members are improved.

In the range which is not more than the glass transition temperature of the cardo type polymer contained resin film, it is possible that the linear expansion coefficient (CTE) is not lower than 50 ppm/° C., and it is particularly preferable that the linear expansion coefficient is not lower than 55 ppm/° C. Further, the resin composition having CTE not more than 20 ppm/° C. can be obtained by mixing the filler in the cardo type polymer contained resin film. When the linear expansion coefficient exists in the above range, the cardo type polymer contained resin film can stably be produced by the usual manufacturing method. The linear expansion coefficient can be measured by a thermo-mechanical analyzing apparatus (TMA).

It is possible that heat conductivity of the cardo type polymer contained resin film is not more than 0.50 W/cm²·sec, and it is particularly preferable that the heat conductivity is not more than 0.35 W/cm²·sec. When the heat conductivity exists in the above range, the heat-resistant properties are improved in the cardo type polymer contained resin film.

It is possible that the heat conductivity of the cardo type polymer contained resin film is not lower than 0.10 W/cm²·sec, and it is particularly preferable that the heat conductivity is not lower than 0.25 W/cm²·sec. When the heat conductivity exists in the above range, the cardo type polymer contained resin film can stably be produced by the usual manufacturing method. For example, the heat conductivity can be measured by a disk heat flow meter method (ASTM E1530).

In the via hole which has the diameter ranging from 10 to 100 μm in the cardo type polymer contained resin film, it is possible that a via hole aspect ratio for example is not lower than 0.5, and it is particularly preferable that the via hole aspect ratio is not lower than 1. When the via hole aspect ratio exists in the above range, the resolution is improved in the cardo type polymer contained resin film.

In the via hole which has the diameter ranging from 10 to 100 μm in the cardo type polymer contained resin film, the via hole aspect ratio for example can be set not more than 5, and it is particularly preferable that the via hole aspect ratio is not more than 2. When the via hole aspect ratio exists in the above range, the cardo type polymer contained resin film can stably be produced by the conventional manufacturing method.

In the case where an alternating electric field having the frequency of 1 MHz is applied to the cardo type polymer contained resin film, the dielectric constant can be set for example not more than 4, and it is particularly preferable that the dielectric constant is not more than 3. When the dielectric constant exists in the above range, dielectric characteristics such as high-frequency characteristics are improved in the cardo type polymer contained resin film.

In the case where the alternating electric field having the frequency of 1 MHz is applied to the cardo type polymer contained resin film, it is possible that the dielectric constant is for example not lower than 0.1, and it is particularly preferable that the dielectric constant is not lower than 2.7. When the dielectric constant exists in the above range, the cardo type polymer contained resin film can stably be produced by the conventional manufacturing method.

In the case where the alternating electric field having the frequency of 1 MHz is applied to the cardo type polymer contained resin film, it is possible that the dielectric dissipation factor is for example not more than 0.04, and it is particularly preferable that the dielectric dissipation factor is not more than 0.029. When the dielectric dissipation factor exists in the above range, the dielectric characteristics such as the high-frequency characteristics are improved in the cardo type polymer contained resin film.

In the case where the alternating electric field having the frequency of 1 MHz is applied to the cardo type polymer contained resin film, it is possible that the dielectric dissipation factor is for example not lower than 0.001, and it is particularly preferable that the dielectric dissipation factor is not lower than 0.027. When the dielectric dissipation factor exists in the above range, the cardo type polymer contained resin film can stably be produced by the conventional manufacturing method.

In the cardo type polymer contained resin film, it is possible that 24-hour water absorption (wt %) is not more than 3 wt %, and it is particularly preferable that the 24-hour water absorption is not more than 1.5 wt %. When the 24-hour water absorption exists in the above range, humidity resistance is improved in the cardo type polymer contained resin film.

In the cardo type polymer contained resin film, it is possible that a 24-hour water absorption coefficient (wt %) is for example not lower than 0.5 wt %, and it is particularly preferable that the 24-hour water absorption coefficient is not lower than 1.3 wt %. When the 24-hour water absorption coefficient exists in the above range, the cardo type polymer contained resin film can stably be produced by the conventional manufacturing method.

The characteristics such as the mechanical strength, the heat-resistant properties, the adhesion properties to other members, the resolution, the dielectric characteristics, and humidity resistance, which are required for the lamination type photoimageable solder resist film 328 containing the cardo type polymer, are realized in a well-balanced manner when the cardo type polymer satisfies the above-mentioned physical properties. Therefore, the device mounting board which is excellent in the reliability, the heat-resistant properties, and the position accuracy in mounting the semiconductor device is stably provided.

<Second Embodiment>

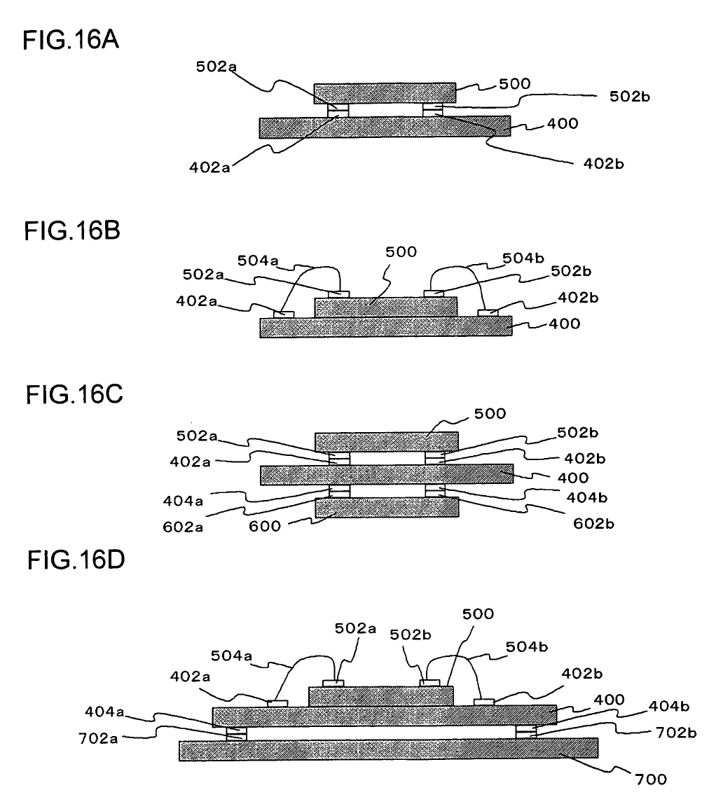

FIGS. 16A to 16D are a sectional view schematically showing various semiconductor apparatuses formed by mounting the semiconductor device on the device mounting board described in the first embodiment.

There are various modes in the semiconductor apparatus formed by mounting the semiconductor device on the device mounting board described in the first embodiment. For example, there is the mode in which the semiconductor device is mounted on the device mounting board by the flip chip connection or the wire bonding connection. There is the mode in which the semiconductor device is mounted on the device mounting board by taking a face up structure or a face down structure. There is the mode in which the semiconductor device is mounted on one side or both sides of the device mounting board. There is the mode in which these various modes are combined.

Specifically, as shown in FIG. 16A, a semiconductor device 500 such as LSI can be mounted on a device mounting board 400 of the first embodiment in the flip chip form. At this point, electrode pads 402a and 402b on the device mounting board 400 are directly connected to electrode pads 502a and 502b of the semiconductor device 500 respectively.

As shown in FIG. 16B, the semiconductor device 500 such as LSI can be mounted on the device mounting board 400 by taking the face up structure. At this point, the electrode pads 402a and 402b located on the top of the device mounting board 400 are connected to the electrode pads 502a and 502b located on the top of the semiconductor element 500 by the wire bonding connection respectively.

As shown in FIG. 16C, the semiconductor device 500 such as LSI can be mounted on the device mounting board 400 in the flip chip form, and a semiconductor device 600 such as IC can be mounted beneath the device mounting board 400 in the flip chip form. At this point, the electrode pads 402a and 402b located on the top of the device mounting board 400 are directly connected to the electrode pads 502a and 502b of the semiconductor device 500 respectively. Further, the electrode pads 404a and 404b located on the lower surface of the device mounting board 400 are directly connected to electrode pads 602a and 602b of the semiconductor device 600 respectively.

As shown in FIG. 16D, the semiconductor device 500 such as LSI can be mounted on the device mounting board 400 by taking the face up structure, and the device mounting board 400 can be mounted on a printed board 700. At this point, the electrode pads 402a and 402b located on the top of the device mounting board 400 are connected to the electrode pads 502a and 502b located on the top of the semiconductor device 500 by wire bonding connection through gold wires 504a and 504b respectively. Further, the electrode pads 402a and 402b located on the lower surface of the device mounting board 400 are directly connected to electrode pads 702a and 702b located on the top of the printed board 700 respectively.

As described in the first embodiment, in the semiconductor apparatus formed by any structure which has the device mounting board 400 including the dielectric layers containing the cardo type polymer on both sides, since the dielectric layers containing the cardo type polymer is excellent in the interlayer adhesion properties between the dielectric layer containing the cardo type polymer and other dielectric layers, the whole of the multilayer dielectric films in the device mounting board 400 is excellent in dimensional stability.

Therefore, the excellent position accuracy is obtained when the semiconductor devices 500 and 600 are mounted on the upper and lower surfaces of the device mounting board 400. Further, the excellent position accuracy is also obtained when the device mounting board 400 is mounted on the printed board 700. Thus, the excellent position accuracy is also obtained in the cases of the flip chip connection and wire bonding connection.

The cardo type polymer contained resin material to which the predetermined modifying agent is added is used as the photoimageable solder resist layer 328 in the second embodiment. However, it is also possible that the cardo type polymer is included in the base material 302 and the dielectric resin film 312 which constitute the four-layer ISB structure.

<Third Embodiment>

A third embodiment provides a device mounting board on which a device is mounted, the device mounting board including a base material; and a lamination film including a plurality of dielectric layers on one surface of the base material, wherein any one of the dielectric layers the second and after, counted from the base material side contains a cardo type polymer, and a layer thickness of the dielectric layer containing the cardo type polymer is larger than that of the dielectric layer which is provided between the dielectric layer containing the cardo type polymer and the base material.

In the cardo type polymer, since the bulky substituent group obstructs the movement of the main chain, the cardo type polymer has the excellent mechanical strength and the heat-resistant properties and the low linear expansion coefficient. Therefore, in the heat cycle, the decrease in adhesion properties and the delamination are suppressed between the dielectric resin layers in the device mounting board. As a result, the device mounting board which is excellent in the reliability and the heat-resistant properties can stably be provided.

Because the layer thickness of the dielectric layer containing the cardo type polymer is larger than that of the dielectric layer provided between the dielectric layer containing the cardo type polymer and the base material, the dielectric layer containing the cardo type polymer immobilizes the whole of device mounting board and suppresses the warp of the whole of device mounting board. Therefore, the device mounting board which is excellent in the position accuracy in mounting the semiconductor device is obtained.

Although the configurations of the third embodiment are described, that the configurations are arbitrarily combined is effective in a mode of the third embodiment. That expression of the third embodiment is converted into the device mounting board manufacturing method or the semiconductor apparatus including the device mounting board is also effective in the mode of the third embodiment.

In the third embodiment, the term of the device mounting board shall mean the board for mounting the semiconductor devices such as the LSI chip and the IC chip, the active elements such as the transistor and the diode, and the passive elements such as the resistor, the coil, and the capacitor. The interposer board in the later-mentioned ISB (registered trademark) structure can be cited as an example of the device mounting board. It is possible that the device mounting board includes the core board having rigidity like a silicon substrate. It is also possible that the device mounting board does not have the core board, but has the coreless structure including the multilayer dielectric film formed by the dielectric resin films.

In the third embodiment, the term of an external terminal shall mean the terminal which can be connected to the external elements the board, and the like. The electrode pad and the solder ball can be cited as an example of the external terminal. However, the external terminal is not limited to the above examples, and the external terminal may include a part of pieces of wiring which can be connected to the external element, the board, and the like and a part of other conductive members.

In the case where the semiconductor devices such as the LSI chip and the IC chip are mounted on the surface of device mounting board, the connection can be achieved by the flip chip connection or the wire bonding connection. In any connecting method, the semiconductor device can be mounted with high position accuracy using the device mounting board.

In the third embodiment, it is possible that the dielectric layer containing the cardo type polymer (referred to as cardo type polymer contained resin film as appropriate) is the dielectric layer in which a conducting member is embedded.

When the wiring is provided in the multilayer film, generally wiring densities in the layers are often different from one another. Therefore, the decrease in adhesion properties between the dielectric resin layers in the multilayer film, the delamination, the warp of the device mounting board, and the like are easy to occur in the heat cycle.

However, in the third embodiment, the first dielectric layer contains the cardo type polymer, and the layer thickness of the first dielectric layer is larger than that of the second dielectric layer. Therefore, the first dielectric layer immobilizes the whole of multilayer resin film to suppress the decrease in adhesion properties between the dielectric resin layers in the multilayer film, the delamination, the warp of the device mounting board, and the like.

It is also possible that the dielectric layer containing the cardo type polymer is the solder resist layer.

As mentioned later, because the cardo type polymer is excellent in the resolution, the decrease in resolution is suppressed even if the film is thickened, so that the dielectric layer containing the cardo type polymer can preferably be used as the solder resist film. Namely, even if the film is thickened, the position accuracy of the solder ball forming hole can favorably be maintained in providing the solder ball.

It is possible that the cardo type polymer is one which is formed of the cross-linked polymer having the carboxyl group and the acrylate group in the same molecular chain.

According to the configuration, the above cardo type polymer is the chemical-crosslink type polymer which has the carboxyl group having the development characteristics and the acrylate group which is of the cross-linking group in the same molecular chain, and radical diffusion is difficult to occur because the cardo type polymer has the bulky substituent group in the main chain. Therefore, the cardo type polymer becomes the photo-setting polymer having the high resolution. In this case, when the polymer is heated, or when the polymer is irradiated with the ultraviolet ray (UV), the acrylate group is cross-linked to form the acryl group, which allows the polymer to be exposed and developed.

In the dielectric layer containing the cardo type polymer, it is possible that the glass transition temperature ranges from 180° C. to 220° C.

According to the configuration, because the dielectric film having the excellent heat-resistant properties is stably obtained, the semiconductor apparatus having the excellent reliability under the high-temperature condition can be obtained.

In the dielectric layer containing the cardo type polymer, it is possible that the linear expansion coefficient ranges from 50 ppm/° C. to 80 ppm/° C.

It is possible that the dielectric layer containing the cardo type polymer contains the filling material such as the filler and the fiber. The granular or fibrous SiO₂ or SiN can be used as the filler. In this case, it is also possible to obtain the dielectric layer formed of the resin composition whose linear expansion coefficient is not more than 20 ppm/K.

According to the configuration, the semiconductor apparatus which is excellent in the reliability and the manufacturing stability can be obtained, because the dielectric film in which the decrease in adhesion properties to other members caused by the heat cycle is suppressed is stably obtained.

In the dielectric layer containing the cardo type polymer, when the alternating electric field is applied at the frequency of 1 MHz, it is possible that the dielectric dissipation factor ranges from 0.001 to 0.04.

According to the configuration, the semiconductor apparatus having the excellent dielectric characteristics can be obtained as a whole, because the dielectric film has the excellent dielectric characteristics such as the high-frequency characteristics.

In the third embodiment, it is possible that the device mounting board further includes the second lamination film including a plurality of the dielectric layers provided on the other surface of the base material, wherein, in the second lamination film, any one of the dielectric layers the second and after, counted from the base material side contains the cardo type polymer, and the layer thickness of the dielectric layer containing the cardo type polymer is larger than that of the dielectric layer which is provided between the dielectric layer containing the cardo type polymer and the base material.

According to the above configuration, the dielectric layer containing the cardo type polymer immobilizes the whole of device mounting board from the both sides, which improves the effect of suppressing the decrease in adhesion properties between the dielectric resin layers in the multilayer film, the delamination, the warp of the device mounting board, and the like.

In the third embodiment, the semiconductor apparatus which includes the device mounting board and the semiconductor device mounted on the device mounting board is also provided.

According to the configuration, the position accuracy is improved in mounting the semiconductor device, because the semiconductor device is bonded onto the device mounting board, in which the warp and the like are suppressed, by the flip chip connection or the wire bonding connection.

It is preferable that the dielectric layer containing the cardo type polymer is one in which the cardo type polymer is contained as the base material. For example, it is possible that the dielectric layer contains the cardo type polymer of not lower than 30 mass %, and it is particularly preferable that the dielectric layer contains the cardo type polymer of not lower than 50 mass %. When the dielectric layer contains the cardo type polymer in the above range, the above characteristics and properties can stably be realized.

Referring to the accompanying drawings, Examples of the third embodiments will be described. In all the drawings, the same constituent is indicated by the same reference numeral, and the description is neglected as appropriately.

### EXAMPLE 1

FIG. 24B is a sectional view showing the device mounting board including the four-layer ISB structure according to Example 1.

The device mounting board has the structure in which a dielectric resin film 1312 and a photoimageable solder resist film 1328 are sequentially laminated on the upper surface of a base material 1302. The device mounting board also has the structure in which the dielectric resin film 1312 and the photoimageable solder resist film 1328 are sequentially laminated on the lower surface of the base material 1302.

A through-hole 1327 which pierces through the base material 1302, the dielectric resin film 1312, and the photoimageable solder resist film 1328 is made.

A part of the piece of wiring made of a copper film 1308, a part of the piece of wiring made of a copper film 1320, a part of a via hole 1311, and the like are embedded in the base material 1302. A part of the piece of the wiring made of the copper film 1308, a part of the piece of the wiring made of the copper film 1320, wiring 1309, a part of the via hole 1311, a part of a via hole 1323, and the like are embedded in the dielectric resin film 1312. A part of the piece of the wiring made of the copper film 1320, a part of the via hole 1323, and the like are embedded in the photoimageable solder resist film 1328. An opening 1326 is provided in the photoimageable solder resist film 1328.

The material used for the base material 1302 is not particularly limited to the glass epoxy board, but any material having the moderate rigidity can be used as the base material 1302. For example, the resin board and the ceramic board can be used as the base material 1302. More specifically, the base material which is excellent in the high-frequency characteristics because of the low dielectric constant can be used. Namely, examples of the base material include polyphenyl ethylene (PPE), bismaleimide triazine resins (BT-resin), polytetrafluoro-ethylene (registered trade name; Teflon), polyimide, liquid crystal polymer (LCP), polynorbornene (PNB), epoxy resins, acrylic resins, ceramics, the mixture of ceramic and the organic base material.

The resin material used for the dielectric resin film 1312 is one which is softened by heating and by which the dielectric resin film 1312 can be thinned to a certain level. Particularly the resin material, which has the low dielectric constant and the excellent high-frequency characteristics, can preferably be used.

It is possible that the dielectric resin film 1312 contains the filling material such as the filler and the fiber. For example, the granular or fibrous SiO₂ or SiN can be used as the filler.

The photoimageable solder resist film 1328 contains the cardo type polymer. The photoimageable solder resist film 1328 is larger than the dielectric resin film 1312 in a film thickness.

In the cardo type polymer, the bulky substituent group obstructs the movement of the main chain, which results in the excellent mechanical strength, the excellent heat-resistant properties, and the low linear expansion coefficient. Therefore, the decrease in adhesion properties, the delamination, and the like are suppressed among the base material 1302, the dielectric resin film 1312, and the photoimageable solder resist film 1328 in the heat cycle. As a result, the reliability and the heat-resistant properties are improved in the device mounting board according to Example 1.

Since the layer thickness of the photoimageable solder resist 1328 containing the cardo type polymer is larger than that of the dielectric resin film 1312 provided between the photoimageable solder resist 1328 and the base material 1302, the photoimageable solder resist 1328 immobilizes the whole of device mounting board and suppresses the warp of the whole of device mounting board. Therefore, the position accuracy is improved when the semiconductor device is mounted on the device mounting board.

Because the cardo type polymer is excellent in the resolution as mentioned later, even if the photoimageable solder resist film 1328 is thickened, the decrease in resolution is suppressed, so that the photoimageable solder resist film 1328 can preferably be used as the solder resist film. Namely, even if the photoimageable solder resist film 1328 is thickened, the position accuracy of the opening 1326 which is used for the solder ball forming hole can favorably be maintained in providing the solder ball.

The multilayer wiring structure including the wiring formed of copper film 1308, the wiring formed of the copper film 1320, the wiring 1309, the via hole 1311 and the via hole 1323 is not limited to the copper wiring. For example, the aluminum wiring, the aluminum alloy wiring, the copper alloy wiring, the wire-bonded gold wiring, the gold alloy wiring, the wiring formed of these pieces of wiring, and the like can also be used as the multilayer wiring structure.

It is also possible that active elements such as the transistor and the diode and passive elements such as the capacitor and the resistor are provided on the surface of or inside the four-layer ISB structure. It is also possible that the active elements or the passive elements are connected to the multilayer wiring structure in the four-layer ISB and connected to the external conductive member through the via hole 1323 and the like.

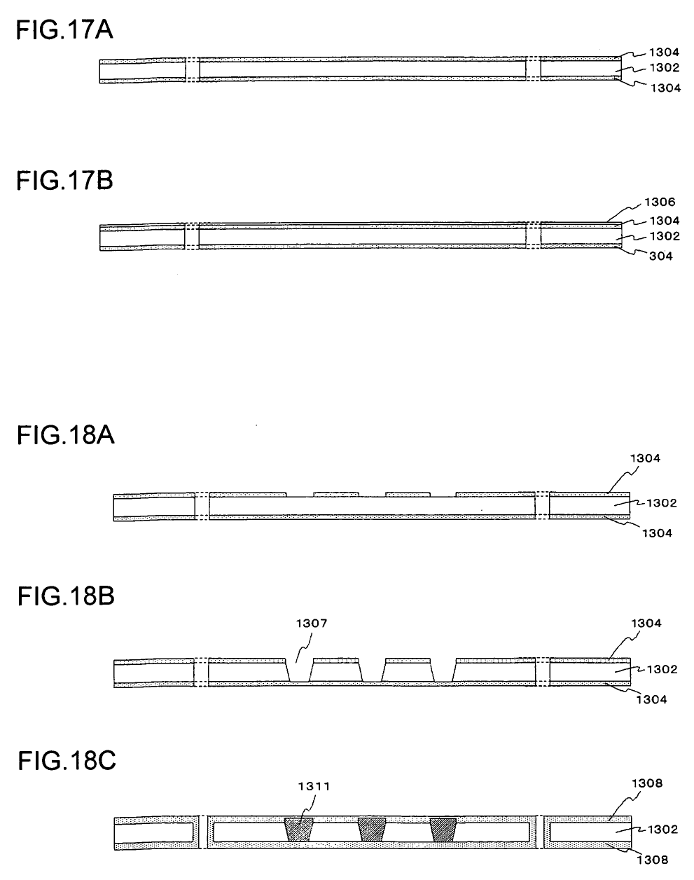

FIGS. 17A to 24B are a process sectional view showing the procedure of manufacturing the device mounting board including the four-layer ISB structure according to Example 1.

In manufacturing the device mounting board including the four-layer ISB structure according to Example 1, as shown in FIG. 17A, the base material 1302 is prepared. The base material 1302 is formed by the glass epoxy board to which the copper foils 1304 are bonded. The holes having diameters of about 150 nm are made in the copper foil 1304. At this point, the thickness of the base material 1302 ranges from about 37.5 μm to about 42.5 μm, and the thickness of the copper foil 1304 ranges from about 10 μm to about 15 μm.

Instead of the copper foil 1304, it is also possible to use the aluminum foil. Further, it is also possible to use the copper alloy foil, the aluminum alloy foil, and the like. Instead of the conductive member containing copper, it is also possible to use the conductive member containing other metals such as aluminum or these alloys.

Then, as shown in FIG. 17B, a photo-etching resist layer 1306 is laminated on the upper surface of the copper foil 1304.

Then, the patterning is performed to the photo-etching resist layer 1306 by performing the exposure with the glass having the light-shielding range as the mask (not shown). Then, as shown in FIG. 18A, using the photo-etching resist layer 1306 as the mask, the patterning is performed to the copper foil 1304.

Then, as shown in FIG. 18B, the patterning is performed to the base material 1302 to make via holes 1307 having the diameters of about 150 nm.

In Example 1, the chemical etching process with the chemicals is adopted as the method of forming the via hole 1307. However, the machining, the dry etching with plasma, the laser machining, and the like can also be used. The photo-etching resist layer 1306 is removed after the etching.

As shown in FIG. 18C, the inside of the via hole 1307 is roughened and washed by a wet process. Then, the via hole 1307 is filled with the conductive material by the electroless plating ready for the high aspect ratio and the electrolytic plating to form a via hole 1311, and the copper films 1308 are formed over the surfaces.

For example, the via hole 1311 can be formed in the following manner. After the thin film whose thickness ranges from about 0.5 to about 1 μm is formed over the surface by the electroless copper plating, the film having the thickness of about 20 μm is formed by the electrolytic plating. Usually palladium is used as the electroless plating catalyst. In order to cause the electroless plating catalyst to adhere to the flexible dielectric resin, palladium is contained in the aqueous solution while being in the complex state, and the flexible dielectric base material is dipped to cause the palladium complex to adhere to the surface of the dielectric base material. In the state of things, the nuclei for starting the plating onto the surface of the flexible dielectric base material can be formed by reducing the palladium complex to the metal palladium with the reducing agent.

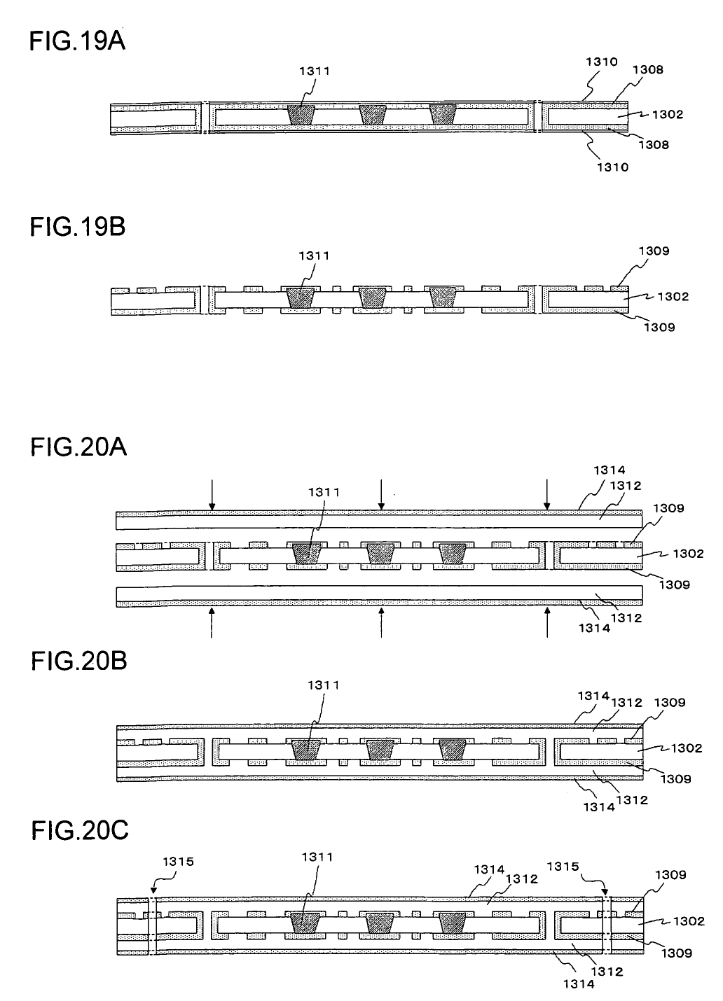

Then, as shown in FIG. 19A, photo-etching resist layers 1310 are laminated onto the top surfaces of the upper and lower copper films 1308. Then, the patterning is performed to the photo-etching resist layer 1310 by performing the exposure with glass having the light-shielding range (not shown) as the mask.

As shown in FIG. 19B, the wiring 1309 made of copper is formed by etching the copper film 1308 formed of the copper plating layer using the photo-etching resist layer 1310 as the mask. For example, the wiring pattern can be formed by spraying the point exposed from the resist with the chemical etching solution to remove the unnecessary copper plating. The photo-etching resist layer 1310 is removed after the etching.

As shown in FIG. 20A, in order to form the dielectric resin film 1312, the resin films with copper foils 1314 are bonded to the top surfaces of the upper wiring 1309 and the lower wiring 1309. The thickness of the resin film for forming the dielectric resin film 1312 ranges for example from about 22.5 μm to about 27.5 μm, and the thickness of the copper foil 1314 ranges for example from about 10 μm to about 15 μm.

In the bonding method, the dielectric resin film 1312 with copper foil is caused to come into contact with the base material 1302 and the wiring 1309, and the base material 1302 and the wiring 1309 are fitted into the dielectric resin film 1312. Then, as shown in FIG. 20B, the dielectric resin film 1312 is heated in a vacuum or under a reduced pressure to bond the dielectric resin film 1312 to the base material 1302 and the wiring 1309.

It is not always necessary that the dielectric resin film 1312 is formed by the bonding. For example, it is possible that the dielectric resin film 1312 is formed by applying and drying the liquid resin composition. It is possible that the dielectric resin film 1312 is formed by the methods, such as the spin coating method, the curtain coating method, roll coating method, and the dip coating method, which are excellent in the coating evenness, the thickness control, and the like. In this case, the copper foil can be separately formed after the dielectric resin film 1312 is formed.

As shown in FIG. 20C, the copper foil 1314 is irradiated with the X-ray to make holes 1315 which pierce through the copper foil 1314, the dielectric resin film 1312, the wiring 1309, and the base material 1302. Alternatively, it is possible that the holes 1315 are made by the laser irradiation or the drilling.

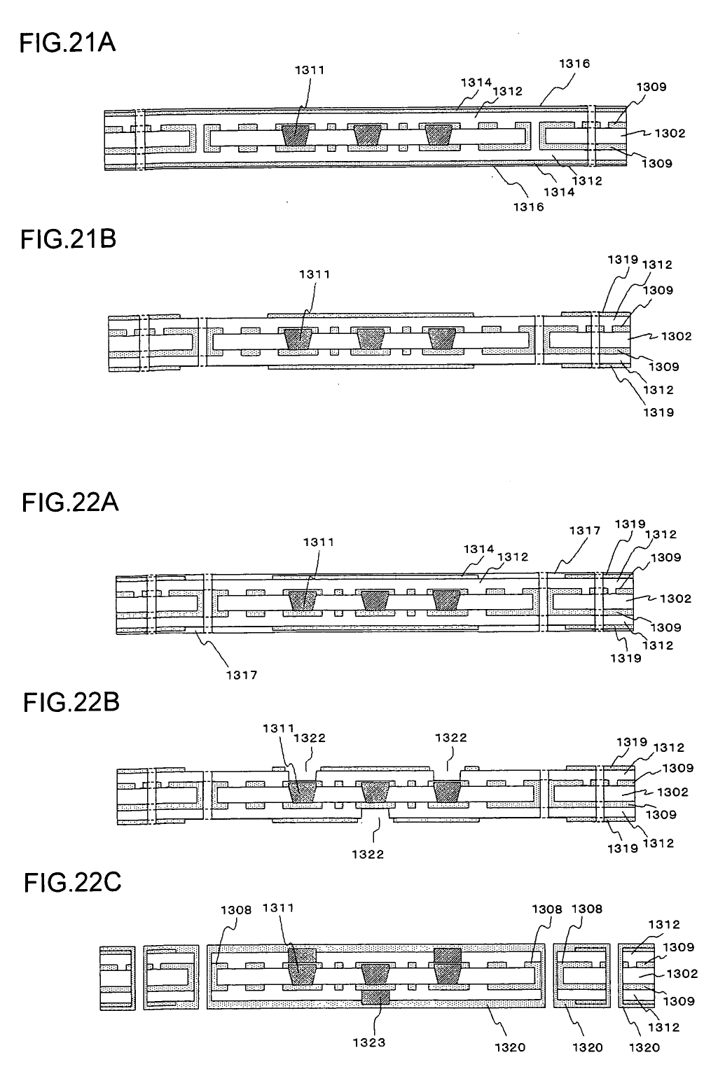

As shown in FIG. 21A, photo-etching resist layers 1316 are laminated on the top surfaces of the upper and lower copper foils 314. Then, the patterning is performed to the photo-etching resist layer 1316 by performing the exposure with the glass having the light-shielding range (not shown) as the mask.

As shown in FIG. 21B, wiring 1319 made of copper is formed by etching the copper foil 1314 with the photo-etching resist layer 1316 as the mask. For example, the wiring pattern can be formed by spraying the point exposed from the resist with a chemical etching solution to remove the unnecessary copper foil. The photo-etching resist layer 1316 is removed after the etching.

As shown in FIG. 22A, photo-etching resist layers 1317 are laminated onto the top surfaces of the upper wiring 1319 and the lower wiring 1319. Then, the patterning is performed to the photo-etching resist layer 1317 by performing the exposure with the glass having the light-shielding range (not shown) as the mask.

As shown in FIG. 22B, the patterning is performed to the wiring 1319 and the dielectric resin film 1312 with the photo-etching resist layer 1317 as the mask to make via holes 1322 having the diameters of about 150 nm. The photo-etching resist layer 1317 is removed after the patterning.

In Example 1, the chemical etching process with the chemicals is adopted as the method of forming the via holes 1322. However, the machining, the dry etching with plasma, the laser machining, and the like can also be used.

As shown in FIG. 22C, the inside of the via hole 1322 is roughened and washed by the wet process. Then, the via hole 1322 is filled with the conductive material by the electroless plating ready for the high aspect ratio and the electrolytic plating in order to form the via hole 1323, and copper films 1320 are formed over the surfaces.

For example, the via hole 1323 can be formed in the following manner. After the thin film whose thickness ranges from about 0.5 to about 1 μm is formed over the surface by the electroless copper plating, the film having the thickness of about 20 μm is formed by the electrolytic plating. Usually palladium is used as the electroless plating catalyst. In order to cause the electroless plating catalyst to adhere to the flexible dielectric resin, palladium is contained in an aqueous solution while being in the complex state, and the flexible dielectric base material is dipped to cause the palladium complex to adhere to the surface of the dielectric base material. In the state of things, the nuclei for starting the plating onto the surface of the flexible dielectric base material can be formed by reducing the palladium complex to the metal palladium with the reducing agent.

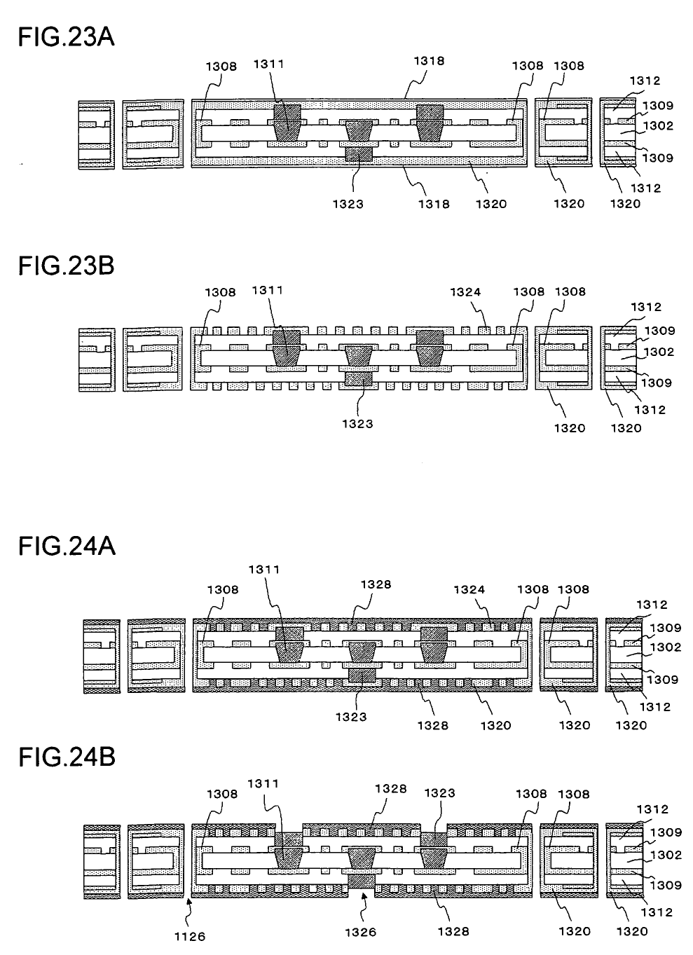

Then, as shown in FIG. 23A, photo-etching resist layers 1318 are laminated onto the top surfaces of the upper and lower copper films 1320. Then, the patterning is performed to the photo-etching resist layer 1318 by performing the exposure with glass having the light-shielding range (not shown) as the mask.

As shown in FIG. 23B, wiring 1324 made of copper is formed by etching the copper film 1320 using the photo-etching resist layer 1318 as the mask. For example, the wiring pattern can be formed by spraying the point exposed from the resist with the chemical etching solution to remove the unnecessary copper foil.

As shown in FIG. 24A, the photoimageable solder resist layers 1328 containing the cardo type polymers are laminated onto the top surfaces of the upper wiring 1324 and the lower wiring 1324.

As shown in FIG. 24B, the patterning is performed to the photoimageable solder resist layer 1328 by performing the exposure with the glass having the light-shielding range as the mask. Then, the wiring 1324 is etched using the photoimageable solder resist layer 1328 as the mask so that the via hole 1323 formed inside the via hole 1322 is exposed, and the opening 1326 having the diameter of about 150 nm is formed.

In Example 1, the chemical etching process with the chemicals is adopted as the method of forming the opening 1326. However, the machining, the dry etching with plasma, the laser machining, and the like can also be used. Then, the gold plating is performed to the exposed via hole 1323 (not shown). Alternatively, it is also possible that the solder ball is directly formed in the exposed via hole 1323.

For the sake of convenience, the description of the semiconductor device is neglected. However, usually the semiconductor devices such as the LIS chip and the IC chip are mounted on the surface of the four-layer ISB structure by the flip chip connection or the wire bonding connection.

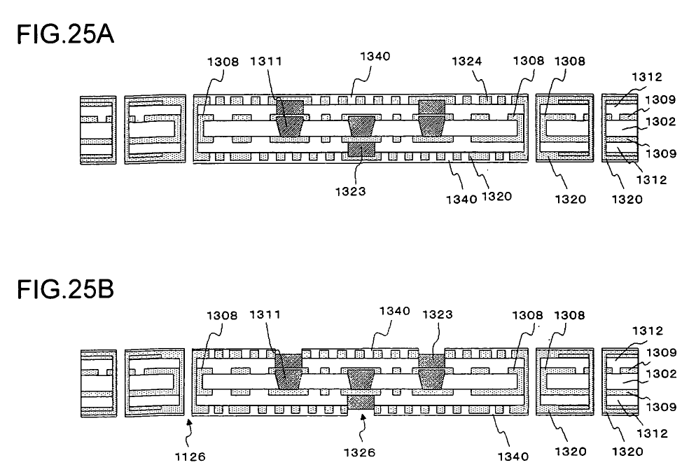

For the sake of comparison, the manufacturing procedure with the conventional photoimageable solder resist film will de described. In the case of the use of the conventional photoimageable solder resist, the manufacturing procedure shown in FIGS. 25A and 25B is performed after the manufacturing procedure shown in FIGS. 17A to 23B.

Namely, in the case of the use of the conventional photoimageable solder resist film, after the manufacturing process shown in FIG. 23B, conventional photoimageable solder resist layers 1340 are laminated onto the top surfaces of the upper wiring 1324 and the lower wiring 1324 so that the film thickness becomes about 35 μm as shown in FIG. 25A. Alternatively, it is possible that the conventional photoimageable solder resist solutions are applied by the spin coating method or the like and dried to form the conventional photoimageable solder resist layers 1340.

As shown in FIG. 25B, the patterning is performed to the conventional photoimageable solder resist layer 1340 by performing the exposure with the glass having the light-shielding range as the mask. Then, the wiring 1324 is etched using the conventional photoimageable solder resist layer 1340 as the mask so that the via hole 1323 formed inside the via hole 1322 is exposed, and the opening 1326 having the diameter of about 150 nm is formed.

In the manufacturing procedure with the conventional photoimageable solder resist layers, the chemical etching process with the chemicals is adopted as the method of forming the opening 1326. In addition, the machining, the dry etching with plasma, the laser machining, and the like can also be used. Then, the gold plating is performed to the exposed via hole 1323 (not shown). Alternatively, it is also possible that the solder ball is directly formed in the exposed via hole 1323.

The effect of using the dielectric resin film made of the resin material containing the cardo type polymer, which is obtained by adding the predetermined modifying agent, in Example 1 will be described below.

In Example 1, it is possible that both the negative type resist film and the positive type resist film are used as the photoimageable solder resist film 1328. However, in the case where the cardo type polymer has the carboxyl group and the acrylate group in the same molecular chain, usually the negative type resist is used as the photoimageable solder resist film 1328.

As used herein the term of the negative type photoimageable solder resist film 1328 shall mean the dielectric coating film in which a structural change only in the photosensitized portion is made in order not to be dissolved in solvent.

Because the photoimageable solder resist film 1328 is used during the soldering, the excellent durability such as the heat-resistant properties and the high elasticity are required for the photoimageable solder resist film 1328. In Example 1, because the negative type photoimageable solder resist film 1328 containing the particular polymer described later is used, the photoimageable solder resist film 1328 has the excellent durability such as the heat-resistant properties and the high elasticity.

The lamination type photoimageable solder resist film 1328 used in Example 1 is not the photoimageable solder resist which is formed by applying the usual stock solution, but the lamination type photoimageable solder resist film 1328 which is formed by bonding the photoimageable solder resist thin film. The photoimageable solder resist film 1328 is bonded to the semiconductor substrate and the like under the proper temperature and pressure conditions while being softened to a certain level.

The thickness of the material film of lamination type photoimageable solder resist film 1328 before bonding is not particularly limited. However, for example, it is possible that the thickness is not lower than 30 μm, and particularly it is preferable that the thickness is not lower than 50 μm. With reference to the film thickness of the lamination type photoimageable solder resist film 1328 obtained by bonding the material film, for example, it is possible that the thickness is not lower than 30 μm, and it is particularly preferable that the thickness is not lower than 50 μm. The mechanical strength, there liability, and productivity are improved when the thickness of the material film or the lamination type photoimageable solder resist film 1328 exists in the above range.

For example, it is possible that the thickness of the material film of lamination type photoimageable solder resist film 1328 before bonding is not more than 150 μm, and it is particularly preferable that the thickness is not more than 100 μm. Further, the thickness of the lamination type photoimageable solder resist film 1328 obtained by bonding the material film is not lower not more than 150 μm, and it is particularly preferable that the thickness is not more than 100 μm. When the thickness of the material film or the lamination type photoimageable solder resist film 1328 exists in the above range, the insulating properties and the flatness of board surface are improved in the photoimageable solder resist film 1328.

Even if the lamination type photoimageable solder resist film 1328 is thickened, when the thickness of the lamination type photoimageable solder resist film 1328 exists in the above-mentioned range, the use of the material film containing the later-mentioned cardo type polymer which is excellent in the resolution improves the workability during the process of curing the photoimageable solder resist film 1328 by the UV irradiation.

When compared with the thickness of about 35 μm of the conventional resin material used for the photoimageable solder resist layer, the thickness of the photoimageable solder resist layer 1328 in Example 1 ranges from about 0.86 times to about 4.3 times. When compared with the thickness ranging from about 22.5 μm to about 27.5 μm of the conventional resin material used for the dielectric resin film 1312, the thickness of the photoimageable solder resist layer 1328 in Example 1 ranges from about 1.26 times to about 6 times.

It is possible that the thickness of the photoimageable solder resist layer 1328 is not lower than 25% of the whole thickness of the device mounting board, and it is particularly preferable that the thickness of the photoimageable solder resist layer 1328 is not lower than 30% of the whole thickness of the device mounting board. When the relative thickness of the lamination type photoimageable solder resist film 1328 exists in the above range, the insulating properties and the mechanical strength are improved.

It is possible that the thickness of the photoimageable solder resist layer 1328 is for example not more than 50% with respect to the whole thickness of the device mounting board, and it is particularly preferable that the thickness of the photoimageable solder resist layer 1328 is not more than 40% with respect to the whole thickness of the device mounting board. When the relative thickness of the lamination type photoimageable solder resist film 1328 exists in the above range, the pressure can be reduced during the bonding of the lamination type photoimageable solder resist film 1328, and the stress applied to the whole of device mounting board can also be suppressed.

Even if the lamination type photoimageable solder resist film 1328 is thickened, when the thickness of the lamination type photoimageable solder resist film 1328 exists in the range, the use of the material film containing the later-mentioned cardo type polymer which is the excellent for the resolution improves the workability during a process of curing the photoimageable solder resist film 1328 by the UV irradiation.

In the lamination type photoimageable solder resist film 1328 containing the cardo type polymer, the later-mentioned desirable characteristics are imparted by curing the lamination type photoimageable solder resist film 1328 in the post-baking process aside from the above-mentioned exposure and development process.

On the other hand, as shown in FIGS. 25A and 25B, in the case of the use of the conventional photoimageable solder resist layer 1340, the amount of warp in the whole of four-layer ISB structure, which is caused by the differences in wiring density, thickness, and material in the dielectric resin film 1312 located directly below the photoimageable solder resist layer 1340 and the base material 1302, tends to increase when the film thickness of each layer in the four-layer ISB structure is made thinner.

Therefore, in order to suppress the amount of warp of the four-layer ISB structure, it is necessary to thicken each layer in the four-layer ISB structure. Accordingly, it is difficult that the four-layer ISB structure is thinned and miniaturized.

When countermeasures for suppressing the amount of warp of the four-layer ISB structure are not taken, the flatness of the four-layer ISB structure is decreased. Therefore, sometimes contact properties are decreased when the device is connected to the wiring board in the flip chip state.

On the contrary, since the later-mentioned cardo type polymer which is excellent in the resolution and the rigidity is used in the four-layer ISB structure of Example 1, the photoimageable solder resist layer 1328 can be thickened without decreasing the resolution, which imparts the excellent rigidity to the photoimageable solder resist layer 1328. Therefore, in the whole of four-layer ISB structure, the amount of warp caused by the differences in wiring density, thickness, and material in the dielectric resin film 1312 located directly below the photoimageable solder resist layer and the base material 1302 can be suppressed. As a result, even if the thicknesses of the dielectric resin film 1312 and the base material 1302 are made thinner than usual, the flatness of the whole of four-layer ISB structure can be maintained.

Namely, even if the photoimageable solder resist layer 1328 which has the thickness larger than usual is used, the resultant thickness of the whole of four-layer ISB structure can be decreased. Further, the resin material of Example 1 is excellent in moisture-absorption characteristics when compared with the conventional material, so that the adhesion properties between the photoimageable solder resist layer 1328 and the member which is in contact with the photoimageable solder resist layer 1328 can be improved. Accordingly, the highly densified four-layer ISB structure having high device reliability can be provided.

Since the four-layer ISB structure of Example 1 has the excellent flatness, the contact properties are improved when the device is connected to the wiring board by the flip chip connection and the like. Further, the contact properties are improved when the semiconductor device is mounted by the flip chip connection and the like. Therefore, when the four-layer ISB of Example 1 is used, the miniaturized semiconductor apparatus which has a low-profile and the high reliability can be provided.

In order to realize the lamination type photoimageable solder resist film 1328 whose thickness is larger than that of the conventional lamination type photoimageable solder resist film, it is effective to use the cardo type polymer having the later-mentioned particular structure. Because the later-mentioned cardo type polymer has the excellent workability, the material film having the excellent insulating properties can be formed while being thicker than usual.

It is possible that the lamination type photoimageable solder resist film 1328 contains the cardo type polymer. The cardo type polymer is a general term for the polymer having the structure in which the cyclic group is directly bonded to the polymer main chain as shown in Chemical Formula III.

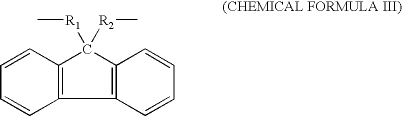

Wherein, R₁ and R₂ express bivalent groups such as the alkylene group and the group containing the aromatic ring.

Namely, the cardo type polymer shall mean the polymer having the structure in which the bulky substituent group containing the quaternary carbon atom is substantially perpendicular to the main chain.

It is possible that cyclic portion includes either the saturated bond or the unsaturated bond. In addition to the carbon atom, it is possible that cyclic portion includes atoms such as the nitrogen atom, the oxygen atom, the sulfur atom, and the phosphorus atom. It is possible that the cyclic portion is formed in the polycycle or the condensed ring. It is possible that the cyclic portion is bonded to other carbon chains and is cross-linked as well.

As shown in Chemical Formula IV, an example of the bulky substituent group includes the cyclic group such as the fluorenyl group which includes the condensed ring having the structure in which six-membered rings are bonded to the both sides of the five-membered ring and the remaining one carbon atom of the five-membered ring is bonded to the main chain.
[Chemical Formula IV]

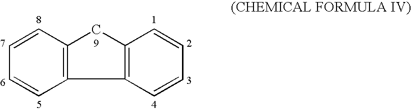

The fluorenyl group is one in which the 9-position carbon atom of fluolene is dehydrogenized. In the cardo type polymer, as shown in Chemical Formula III, the fluorenyl group is bonded to the carbon atom of the alkyl group which is of the main chain at the position of the dehydrogenized carbon atom.

Since the cardo type polymer is one which has the above structure, the cardo type polymer has the following effects:
(1) Rotation constraint of polymer main chain.
(2) Conformation control of main chain and side chain.
(3) Packing obstruction between molecules.
(4) Increase in aromaticityby introducing aromatic substituent group to side chain.

Accordingly, the cardo type polymer has the features such as the high heat-resistant properties, the solvent solubility, the high transparency, the high refractive index, the low birefringence, and the higher gas permeability.

The material film of the lamination type photoimageable solder resist film 1328 before bonding can be formed in the thick film while the void and the unevenness are prevented from producing by using the cardo type polymer and the predetermined additive. Further, since the material film containing the cardo type polymer contains the cardo type polymer of high glass transition temperature, many other components having a flow property can be included. Therefore, the material film containing the cardo type polymer is easily softened by heating, so that the material film containing the cardo type polymer has good embedding properties. Similarly, the small number of voids exists in the lamination type photoimageable solder resist film 1328 in the bonded device mounting board, and the little unevenness exists in the lamination type photoimageable solder resist film 1328. Therefore, the lamination type photoimageable solder resist 1328 having the small number of voids can secure the accurate film thickness.

Sometimes the resolution is decreased when the conventional photoimageable solder resist film is thickened. On the contrary, in Example 1, since the material film containing the cardo type polymer having the excellent resolution described later, even if the photoimageable solder resist film is thickened, the lamination type photoimageable solder resist 1328 having the excellent resolution can be formed.

It is also possible that the cardo type polymer is cross-linked polymer having the carboxyl group and the acrylate group in the same molecular chain. Conventionally, the blend of the carboxyl group oligomer having development properties and the polyfunctional acrylate is used as the general photosensitive varnish. However, the general photosensitive varnish still has room for improvement in the resolution. When the cardo type polymer formed by the cross-linked polymer having the carboxyl group and the acrylate group in the same molecular chain is used instead of the general photosensitive varnish, the cardo type polymer has the carboxyl group having the development properties and the acrylate group which is of the cross-linking group in the same molecular chain, and the cardo type polymer also has the bulky substituent group in the main chain, so that the radical diffusion is difficult to occur. Therefore, in the photoimageable solder resist film 1328 containing the cardo type polymer, there is the advantage that the resolution is improved.

It is desirable that the photoimageable solder resist film 1328 formed of the cardo type polymer contained resin film satisfies the following physical properties. The following physical properties are the value for the resin portion which does not include the filler and the like, and the physical properties can be appropriately adjusted by adding the filler and the like.

In the cardo type polymer contained resin film, it is possible that the glass transition temperature (Tg) is for example not lower than 180° C., and it is particularly preferable that the glass transition temperature (Tg) is not lower than 190° C. When the glass transition temperature (Tg) exists in the above range, the heat-resistant properties are improved in the cardo type polymer contained resin film.

In the cardo type polymer contained resin film, it is possible that the glass transition temperature (Tg) is for example not more than 220° C., and it is particularly preferable that the glass transition temperature (Tg) is not more than 210° C. When the glass transition temperature (Tg) exists in the above range, the cardo type polymer contained resin film can stably be produced by the conventional manufacturing method. The glass transition temperature can be measured by the dynamic viscoelasticity measurement (DMA) of a bulk sample for example.

In the range which is not more than the glass transition temperature (Tg) of the cardo type polymer contained resin film, it is possible that the linear expansion coefficient (CTE) is not more than 80 ppm/° C., and it is particularly preferable that the linear expansion coefficient is not more than 75 ppm/° C. When the linear expansion coefficient exists in the above range, the adhesion properties between the cardo type polymer contained resin film and other members are improved.

In the range which is not more than the glass transition temperature (Tg) of the cardo type polymer contained resin film, it is possible that the linear expansion coefficient (CTE) is not lower than 50 ppm/° C., and it is particularly preferable that the linear expansion coefficient is not lower than 55 ppm/° C. Further, the resin composition having CTE of not more than 20 ppm/° C. can be obtained by mixing the filler in the cardo type polymer contained resin film. When the linear expansion coefficient exists in the above range, the cardo type polymer contained resin film can stably be produced by the conventional manufacturing method. The linear expansion coefficient can be thermo-expansion measured by the thermo-mechanical analysis apparatus (TMA).

It is possible that the heat conductivity of the cardo type polymer contained resin film is for example not more than 0.50 W/cm²·sec, and it is particularly preferable that the heat conductivity is not more than 0.35 W/cm²·sec. When the heat conductivity exists in the above range, the heat-resistant properties are improved in the cardo type polymer contained resin film.

It is possible that the heat conductivity of the cardo type polymer contained resin film is for example not lower than 0.10 W/cm²·sec, and it is particularly preferable that the heat conductivity is not lower than 0.25 W/cm²·sec. When the heat conductivity exists in the above range, the cardo type polymer contained resin film can stably be produced by the conventional manufacturing method. For example, the heat conductivity can be measured by the disk heat flow meter method (ASTM E1530).

In the via hole which has the diameter ranging from 10 to 100 μm in the cardo type polymer contained resin film, it is possible that the via hole aspect ratio is for example not lower than 0.5, and it is particularly preferable that the via hole aspect ratio is not lower than 1. When the via hole aspect ratio exists in the above range, the resolution is improved in the cardo type polymer contained resin film.

In the via hole which has the diameter ranging from 10 to 100 μm in the cardo type polymer contained resin film, it is possible that the via hole aspect ratio is not more than 5, and it is particularly preferable that the via hole aspect ratio is not more than 2. When the via hole aspect ratio exists in the above range, the cardo type polymer contained resin film can stably be produced by the conventional manufacturing method.

In the case where an alternating electric field having the frequency of 1 MHz is applied to the cardo type polymer contained resin film, it is possible that the dielectric constant is not more than 4, and it is particularly preferable that the dielectric constant is not more than 3. When the dielectric constant exists in the above range, the dielectric characteristics such as the high-frequency characteristics are improved in the cardo type polymer contained resin film.

In the case where the alternating electric field having the frequency of 1 MHz is applied to the cardo type polymer contained resin film, it is possible that the dielectric constant is not lower than 0.1, and it is particularly preferable that the dielectric constant is not lower than 2.7. When the dielectric constant exists in the above range, the cardo type polymer contained resin film can stably be produced by the conventional manufacturing method.

In the case where the alternating electric field having the frequency of 1 MHz is applied to the cardo type polymer contained resin film, it is possible that the dielectric dissipation factor is not more than 0.04, and it is particularly preferable that the dielectric dissipation factor is not more than 0.029. When the dielectric dissipation factor exists in the above range, the dielectric characteristics such as the high-frequency characteristics are improved in the cardo type polymer contained resin film.

In the case where the alternating electric field having the frequency of 1 MHz is applied to the cardo type polymer contained resin film, it is possible that the dielectric dissipation factor is not lower than 0.001, and it is particularly preferable that the dielectric dissipation factor is not lower than 0.027. When the dielectric dissipation factor exists in the above range, the cardo type polymer contained resin film can stably be produced by the conventional manufacturing method.

In the cardo type polymer contained resin film, it is possible that 24-hour water absorption (wt %) is not more than 3 wt %, and it is particularly preferable that the 24-hour water absorption is not more than 1.5 wt %. When the 24-hour water absorption (wt %) exists in the above range, the humidity resistance is improved in the cardo type polymer contained resin film.

In the cardo type polymer contained resin film, it is possible that 24-hour water absorption (wt %) is not lower than 0.5 wt %, and it is particularly preferable that the 24-hour water absorption is not lower than 1.3 wt %. When the 24-hour water absorption (wt %) exists in the above range, the cardo type polymer contained resin film can stably be produced by the conventional manufacturing method.

The characteristics such as the mechanical strength, the heat-resistant properties, the adhesion properties to other members, the resolution, the dielectric characteristics, and humidity resistance, which are required for the lamination type photoimageable solder resist film 1328 containing the cardo type polymer, are realized in a well-balanced manner when the cardo type polymer satisfies the above-mentioned physical properties. Therefore, the device mounting board which is excellent for the reliability, the heat-resistant properties, and the position accuracy in mounting the semiconductor device is stably provided.

### EXAMPLE 2

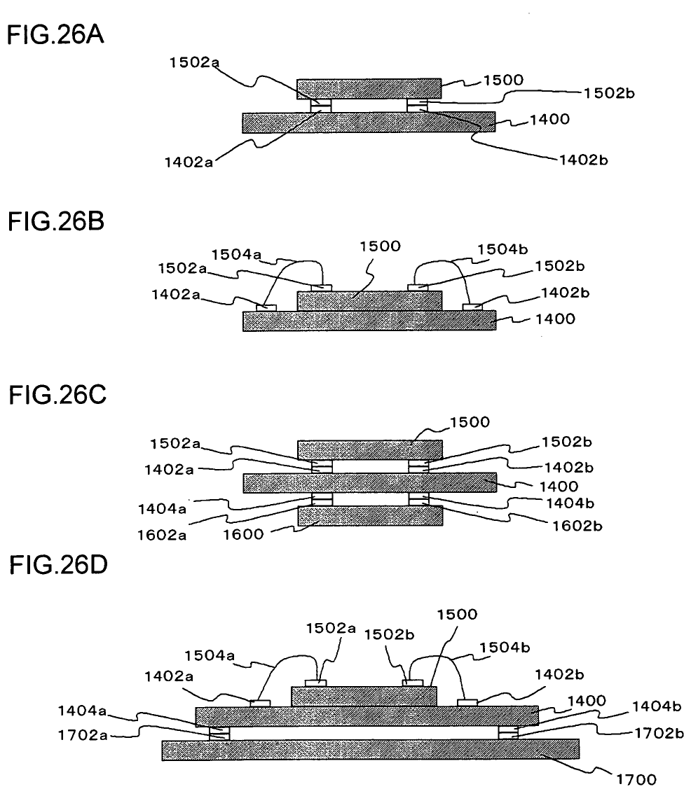

FIGS. 26A to 29D are a sectional view schematically showing various semiconductor apparatuses formed by mounting the semiconductor device on the device mounting board described in Example 1.

There are various modes in the semiconductor apparatus formed by mounting the semiconductor device on the device mounting board described in Example 1. For example, there is the mode in which the semiconductor device is mounted on the device mounting board by the flip chip connection or the wire bonding connection. There is the mode the semiconductor device is mounted on the device mounting board by taking the face up structure or the face down structure. There is the mode in which the semiconductor element is mounted on one side or both sides of the device mounting board. There is the mode in which these various modes are combined.

Specifically, as shown in FIG. 26A, a semiconductor device 1500 such as LSI can be mounted on a device mounting board 1400 of the Example 1 in the flip chip form. At this point, electrode pads 1402a and 1402b on the device mounting board 1400 are directly connected to electrode pads 1502a and 1502b of the semiconductor device 1500 respectively.

As shown in FIG. 26B, the semiconductor device 1500 such as LSI can be mounted on the device mounting board 1400 by taking the face up structure. At this point, the electrode pads 1402a and 1402b located on the top of the device mounting board 1400 are connected to the electrode pads 1502a and 1502b located on the top of the semiconductor device 1500 by the wire bonding connection respectively.

As shown in FIG. 26C, the semiconductor device 1500 such as LSI can be mounted on the device mounting board 1400 in the flip chip form, and a semiconductor device 1600 such as IC can be mounted beneath the device mounting board 1400 in the flip chip form. At this point, the electrode pads 1402a and 1402b located on the top of the device mounting board 1400 are directly connected to the electrode pads 1502a and 1502b of the semiconductor device 1500 respectively. Further, the electrode pads 1404a and 1404b located on the lower surface of the device mounting board 1400 are directly connected to electrode pads 1602a and 1602b of the semiconductor device 1600 respectively.

As shown in FIG. 26D, the semiconductor device 1500 such as LSI can be mounted on the device mounting board 1400 by taking the face up structure, and the device mounting board 1400 can be mounted on a printed board 1700. At this point, the electrode pads 1402a and 1402b located on the top of the device mounting board 1400 are connected to the electrode pads 1502a and 1502b located on the top of the semiconductor device 1500 through gold wires 1054a and 1504b by wire bonding connection respectively. Further, the electrode pads 1404a and 1404b located on the lower surface of the device mounting board 1400 are directly connected to electrode pads 1702a and 1702b located on the top of the printed board 1700 respectively.

As described in Example 1, in the semiconductor apparatus having any structure which has the device mounting board 1400 including the first dielectric layer and the second dielectric layer, since the first dielectric layer containing the cardo type polymer is larger than the second dielectric layer in the layer thickness, the first dielectric layer immobilizes the whole of multilayer dielectric film, and the warp of the whole of multilayer dielectric film is suppressed in the device mounting board 1400.

Therefore, the excellent position accuracy is obtained when the semiconductor devices 1500 and 1600 are mounted on the upper and lower surfaces of the device mounting board 1400. Further, the excellent position accuracy is obtained when the device mounting board 1400 is mounted on the printed board 1700. Thus, the excellent position accuracy can be obtained not only in the case of the flip chip connection but in the case of the wire bonding connection.

Although the configurations of the invention are described, that the configurations are arbitrarily combined is also effective in the mode of the invention. That expression of the invention is converted into the device mounting board manufacturing method or the semiconductor apparatus including the device mounting board is also effective in the mode of the invention.

In Example 2, the photoimageable solder resist layer 1328 contains the cardo type polymer, and the resin material to which the predetermined modifying agent is added is used. However, it is also possible that the cardo type polymer is contained in the base material 1302 and the dielectric resin film 1312 which constitute the four-layer ISB.

The device mounting board having the four-layer ISB (registered trademark) structure described later can be cited as an example of the above device mounting board. However, the device mounting board is not particularly limited to the four-layer ISB structure. It is possible that the multilayer dielectric film included in the device mounting board is the two-layer dielectric film, the three-layer dielectric film, or the multilayer dielectric film having at least five layers.

It is possible that the cardo type polymer is used for the base material, the dielectric resin film, the photoimageable solder resist layer, and the like which constitute ISB except for the four-layer ISB. It is also possible that the cardo type polymer is used for the base material, the dielectric resin film, the photoimageable solder resist layer, and the like which constitute other semiconductor packages.

The multilayer wiring structure is not limited to the copper wiring. For example, the aluminum wiring, the aluminum alloy wiring, the copper alloy wiring., the wire-bonded gold wiring, the gold alloy wiring, the wiring formed by these pieces of wiring, and the like can also be used as the multilayer wiring structure.

It is also possible that active elements such as the transistor and the diode and passive elements such as the capacitor and the resistor are provided on the surface of or in the device mounting board. The semiconductor apparatus can be further integrated by providing such active elements and passive elements.

The device mounting board including the ISB structure is cited as an example of the above-mentioned device mounting board. However, the device mounting board is not particularly limited. For example, it is possible that the device mounting board in Example 2 is used as the so-called printed board.

1. A device mounting board on which a device is mounted, the device mounting board comprising:
a base material;
a first lamination film including a plurality of dielectric layers on one surface of said base material; and
a second lamination film including the plurality of dielectric layers on the other surface of said base material,
wherein, in said first lamination film, any one of the dielectric layers the second and after, counted from said base material side is the dielectric layer containing a first cardo type polymer, the dielectric layer containing the first cardo type polymer being formed by bonding a material film containing the first cardo type polymer, and
in said second lamination film, any one of the dielectric layers the second and after, counted from said base material side is the dielectric layer containing a second cardo type polymer, the dielectric layer containing the second cardo type polymer being formed by bonding a material film containing the second cardo type polymer.

2. A semiconductor apparatus comprising:
a device mounting board according to claim 1; and
a semiconductor device which is mounted on said device mounting board.

3. A device mounting board on which a device is mounted, the device mounting board comprising:
a base material; and
a lamination film including a plurality of dielectric layers on one surface of said base material,
wherein any one of the dielectric layers the second and after, counted from said base material side contains a cardo type polymer, and
a layer thickness of the dielectric layer containing said cardo type polymer is larger than that of the dielectric layer which is provided between the dielectric layer containing said cardo type polymer and said base material.

4. A device mounting board according to claim 3, wherein the dielectric layer containing said cardo type polymer is the dielectric layer in which a conducting member is embedded.

5. A device mounting board according to claim 3, wherein the dielectric layer containing said cardo type polymer is a solder resist layer.

6. A device mounting board according to claim 4, wherein the dielectric layer containing said cardo type polymer is the solder resist layer.

7. A device mounting board according to claim 3, wherein said cardo type polymer is formed of cross-linked polymer which has a carboxylic acid group and an acrylate group in the same molecular chain.

8. A device mounting board according to claim 4, wherein said cardo type polymer is formed of cross-linked polymer which has a carboxylic acid group and an acrylate group in the same molecular chain.

9. A device mounting board according to claim 5, wherein said cardo type polymer is formed of cross-linked polymer which has a carboxylic acid group and an acrylate group in the same molecular chain.

10. A device mounting board according to claim 6, wherein said cardo type polymer is formed of cross-linked polymer which has a carboxylic acid group and an acrylate group in the same molecular chain.

11. A device mounting board according to claim 3, wherein a glass transition temperature of the dielectric layer containing said cardo type polymer ranges from 180° C. to 220° C., and
a dielectric dissipation factor ranges from 0.001 to 0.04 when an alternating electric field having a frequency of 1 MHz is applied to the dielectric layer containing said cardo type polymer.

12. A device mounting board according to claim 4, wherein the glass transition temperature of the dielectric layer containing said cardo type polymer ranges from 180° C. to 220° C., and
the dielectric dissipation factor ranges from 0.001 to 0.04 when the alternating electric field having the frequency of 1 MHz is applied to the dielectric layer containing the cardo type polymer.

13. A device mounting board according to claim 5, wherein the glass transition temperature of the dielectric layer containing said cardo type polymer ranges from 180° C. to 220° C., and
the dielectric dissipation factor ranges from 0.001 to 0.04 when the alternating electric field having the frequency of 1 MHz is applied to the dielectric layer containing said cardo type polymer.

14. A device mounting board according to claim 11, wherein a linear expansion coefficient ranges from 50 ppm/° C. to 80 ppm/° C. in a range lower than or equal to the glass transition temperature of the dielectric layer containing said cardo type polymer.

15. A device mounting board according to claim 3, further comprising the second lamination film including the plurality of dielectric layers provided on the other surface of said base material,
wherein, in said second lamination film, any one of the dielectric layers the second and after, counted from said base material side contains the cardo type polymer, and
the layer thickness of the dielectric layer containing said cardo type polymer is larger than that of the dielectric layer which is provided between the dielectric layer containing said cardo type polymer and said base material.

16. A device mounting board according to claim 4 further comprising a second lamination film including the plurality of dielectric layers provided on the other surface of said base material,
wherein, in said second lamination film, any one of the dielectric layers the second and after, counted from said base material side contains the cardo type polymer, and
the layer thickness of the dielectric layer containing said cardo type polymer is larger than that of the dielectric layer which is provided between the dielectric layer containing said cardo type polymer and said base material.

17. A device mounting board according to claim 5, further comprising the second lamination film including the plurality of dielectric layers provided on the other surface of said base material,
wherein, in said second lamination film, any one of the dielectric layers the second and after, counted from said base material side contains the cardo type polymer, and
the layer thickness of the dielectric layer containing said cardo type polymer is larger than that of the dielectric layer which is provided between the dielectric layer containing said cardo type polymer and said base material.

18. A semiconductor apparatus comprising:
a device mounting board according to claim 3; and
a semiconductor device which is mounted on the device mounting board.

19. A semiconductor apparatus comprising:
a device mounting board according to claim 4; and
a semiconductor device which is mounted on the device mounting board.

20. A semiconductor apparatus comprising:
a device mounting board according to claim 5; and
a semiconductor device which is mounted on the device mounting board.
